(19) United States
(12) Patent Application Publication
(10) Pub. No.: US 2025/0025963 A1
(43) Pub. Date: Jan. 23, 2025

(54) LASER PROCESSING DEVICE AND LASER PROCESSING METHOD

(71) Applicant: HAMAMATSU PHOTONICS K.K., Hamamatsu-shi, Shizuoka (JP)

(72) Inventors: Takeshi SAKAMOTO, Hamamatsu-shi, Shizuoka (JP); Yo SUGIMOTO, Hamamatsu-shi, Shizuoka (JP); Takafumi OGIWARA, Hamamatsu-shi, Shizuoka (JP); Takashi KURITA, Hamamatsu-shi, Shizuoka (JP); Ryo YOSHIMURA, Hamamatsu-shi, Shizuoka (JP)

(73) Assignee: HAMAMATSU PHOTONICS K.K., Hamamatsu-shi, Shizuoka (JP)

(21) Appl. No.: 18/715,221

(22) PCT Filed: Aug. 22, 2022
(86) PCT No.: PCT/JP2022/031623

§ 371 Date: May 31, 2024

(30) Foreign Application Priority Data
Jan. 25, 2022 (JP) 2022-009499

(51) Int. Cl. B23K 26/364

(52) U.S. Cl. CPC B23K 26/364

(57) ABSTRACT

A laser processing device includes a support unit, a laser light source, a spatial light modulator, and a condensing unit. A modulation pattern displayed on a display unit of the spatial light modulator includes a branching pattern for branching laser light into first branched laser light components to form a first groove and second branched laser light components to form a second groove. A distance between the position of the focusing point of the first branched laser light and the position of the focusing point of the second branched laser light adjacent to each other in a direction along the line is larger than a distance between the position of the focusing point of the first branched laser light and the position of the focusing point of the second branched laser light in the width direction of the first groove and the second groove.

### TECHNICAL FIELD

One aspect of the present invention relates to a laser processing device and a laser processing method.

### BACKGROUND ART

When cutting an object along the line, for example, grooving processing for removing the surface layer side of the object along the line may be performed (see, for example, Patent Literatures 1 and 2). In such grooving processing, a groove is formed in the object along the line by irradiating the object with laser light.

### CITATION LIST

### Patent Literature

Patent Literature 1: Japanese Unexamined Patent Publication No. 2007-173475
Patent Literature 2: Japanese Unexamined Patent Publication No. 2017-011040

### SUMMARY OF INVENTION

### Technical Problem

In the above-described techniques, for example, in order to improve takt (work efficiency), at least a first groove and a second groove may be formed in the object along the line by branching the laser light emitted to the object into a plurality of branched laser light components. However, in this case, the focusing points (processing points) of respective branched laser light components may be influenced by each other, which may cause a problem that the first groove and the second groove cannot be formed satisfactorily.

Therefore, it is an object of one aspect of the present invention to form a first groove and a second groove satisfactorily in an object along the line with a laser processing device and a laser processing method for branching laser light and irradiating the object with the branched laser light components.

### Solution to Problem

A laser processing device according to one aspect of the present invention is a laser processing device for forming a groove in an object along a line by irradiating the object with laser light along the line, and includes: a support unit configured to support the object; a laser light source configured to emit the laser light; a spatial light modulator including a display unit on which the laser light emitted from the laser light source is incident and modulates the laser light according to a modulation pattern displayed on the display unit; and a condensing unit configured to condense the laser light modulated by the spatial light modulator onto the object supported by the support unit. The modulation pattern includes a branching pattern for at least branching the laser light into one or more first branched laser light components to form a first groove and one or more second branched laser light components to form a second groove. A distance between a position of a focusing point of the first branched laser light and a position of a focusing point of the second branched laser light adjacent to each other in a direction along the line is larger than a distance between a position of a focusing point of the first branched laser light and a position of a focusing point of the second branched laser light in a width direction of the first groove and the second groove.

In this laser processing device, the distance between the position of the focusing point of the first branched laser light (hereinafter, also referred to as “first processing position”) and the position of the focusing point of the second branched laser light (hereinafter, also referred to as “second processing position”) adjacent to each other in the direction along the line is larger than the distance between the first processing position and the second processing position in the width direction. For this reason, since it is possible to separate the first processing point and the second processing point from each other until the influence on each other (for example, interference between focusing points and the influence of processing in a heat-affected state; the same hereinbelow) is less likely to occur, each of the first groove and the second groove can be reliably formed as an independent groove in the object. Therefore, it is possible to form the first groove and the second groove satisfactorily in the object along the line.

In the laser processing device according to one aspect of the present invention, the second groove may overlap an end portion of the first groove in the width direction of the first groove. In this case, a composite groove including the first groove and the second groove can be formed in the object. Such a composite groove can effectively induce a crack extending from a modified region formed inside the object, for example.

In the laser processing device according to one aspect of the present invention, the branching pattern may branch the laser light into one or more third branched laser light components to form a third groove in addition to the first branched laser light and the second branched laser light, the third groove overlapping an end portion of the second groove in the width direction of the second groove. In this case, it is possible to form a wide composite groove.

In the laser processing device according to one aspect of the present invention, the distance between the position of the focusing point of the first branched laser light and the position of the focusing point of the second branched laser light adjacent to each other in the direction along the line may be larger than a pulse pitch of the laser light. In this case, since the occurrence of a situation in which the distance between the first processing position and the second processing position is too short and accordingly their influence on each other becomes significant is suppressed, it is possible to form the first groove and the second groove satisfactorily in the object.

In the laser processing device according to one aspect of the present invention, a distance between positions of focusing points of the plurality of first branched laser light components in the direction along the line may be larger than a pulse pitch of the laser light. In this case, since it is possible to suppress the occurrence of a situation in which the distance between a plurality of first processing positions is too short and accordingly their influence on each other becomes significant, it is possible to form the first groove satisfactorily in the object.

In the laser processing device according to one aspect of the present invention, a distance between positions of focusing points of the plurality of first branched laser light components in the direction along the line may be smaller than the distance between the position of the focusing point of the first branched laser light and the position of the focusing point of the second branched laser light adjacent to each other in the direction along the line. In this case, the distance between the plurality of first processing positions can be set to a range where they influence each other so that a HAZ (Heat-Affected-Zone) can be suppressed.

In the laser processing device according to one aspect of the present invention, a distance between positions of focusing points of the plurality of second branched laser light components in the direction along the line may be larger than a pulse pitch of the laser light. In this case, since it is possible to suppress the occurrence of a situation in which the distance between a plurality of second processing positions is too short and accordingly their influence on each other becomes significant, it is possible to form the second groove satisfactorily in the object.

In the laser processing device according to one aspect of the present invention, a distance between positions of focusing points of the plurality of second branched laser light components in the direction along the line may be smaller than the distance between the position of the focusing point of the first branched laser light and the position of the focusing point of the second branched laser light adjacent to each other in the direction along the line. In this case, the distance between the plurality of second processing positions can be set to a range where they influence each other so that the HAZ can be suppressed.

In the laser processing device according to one aspect of the present invention, the branching pattern may branch the laser light into the two first branched laser light components and the two second branched laser light components. In this case, since the energy at each focusing point can be reduced, it is possible to suppress the HAZ.

In the laser processing device according to one aspect of the present invention, the branching pattern may branch the laser light into the three first branched laser light components and the three second branched laser light components. In this case, the energy at each focusing point can be further reduced, making it possible to further suppress HAZ.

In the laser processing device according to one aspect of the present invention, the branching pattern may branch the laser light so that focusing points are aligned in a one-dimensional array along the line. Therefore, it is possible to form a narrow composite groove in the object.

A laser processing method according to one aspect of the present invention is a laser processing method for forming a groove in an object along a line by irradiating the object with laser light along the line, and includes a step of emitting the laser light, making the emitted laser light incident on a display unit of a spatial light modulator, modulating the laser light according to a modulation pattern displayed on the display unit, and condensing the modulated laser light onto the object. The modulation pattern includes a branching pattern for at least branching the laser light into one or more first branched laser light components to form a first groove and one or more second branched laser light components to form a second groove. A distance between a position of a focusing point of the first branched laser light and a position of a focusing point of the second branched laser light adjacent to each other in a direction along the line is larger than a distance between a position of a focusing point of the first branched laser light and a position of a focusing point of the second branched laser light in a width direction of the first groove and the second groove.

Also in this laser processing method, it is possible to form the first groove and the second groove satisfactorily in the object along the line.

### Advantageous Effects of Invention

According to one aspect of the present invention, it is possible to form the first groove and the second groove satisfactorily in the object along the line by using the laser processing device and the laser processing method for branching laser light and irradiating the object with the branched laser light components.

### BRIEF DESCRIPTION OF DRAWINGS

FIG. 1 is a configuration diagram of a laser processing device for forming a modified region inside a wafer.

FIG. 2 is a configuration diagram of a laser processing device for performing grooving processing.

FIG. 3 is a plan view of a wafer to be processed.

FIG. 4 is a cross-sectional view of a part of the wafer shown in FIG. 3.

FIG. 5 is a plan view of a part of a street shown in FIG. 3.

FIG. 6 is a diagram showing an example of a case where the position of each focusing point of the first branched laser light and the position of each focusing point of the second branched laser light are viewed from a Z direction.

FIG. 7(a) is a cross-sectional view of a wafer for explaining a laser processing method according to an embodiment. FIG. 7(b) is a cross-sectional view of the wafer showing a continuation of FIG. 7(a). FIG. 7(c) is a cross-sectional view of the wafer showing a continuation of FIG. 7(b).

FIG. 8(a) is a cross-sectional view of the wafer showing a continuation of FIG. 7(c). FIG. 8(b) is a cross-sectional view of the wafer showing a continuation of FIG. 8(a). FIG. 8(c) is a cross-sectional view of the wafer showing a continuation of FIG. 8(b).

FIG. 9(a) is a cross-sectional view of the wafer showing a continuation of FIG. 8(c). FIG. 9(b) is a cross-sectional view of the wafer showing a continuation of FIG. 9(a).

FIG. 10 is an enlarged cross-sectional view of a part of the wafer in FIG. 9(b).

FIG. 11(a) is a cross-sectional view corresponding to FIG. 10 of a wafer according to a modification example. FIG. 11(b) is a cross-sectional view corresponding to FIG. 10 of a wafer according to another modification example. FIG. 11(c) is a cross-sectional view corresponding to FIG. 10 of a wafer according to still another modification example.

FIG. 12 is a cross-sectional view of the wafer showing a continuation of FIG. 9(b).

FIG. 13 is a cross-sectional view corresponding to FIG. 10 of a wafer according to a conventional example.

FIG. 14 is a diagram showing another example of the case where the position of each focusing point of the first branched laser light and the position of each focusing point of the second branched laser light are viewed from the Z direction.

FIG. 15(a) is a diagram showing an example of a case where the position of each focusing point of the first branched laser light, the position of each focusing point of the second branched laser light, and the position of each focusing point of the third branched laser light are viewed from the Z direction. FIG. 15(b) is a cross-sectional view of a wafer showing a composite groove according to a modification example.

FIG. 16(a) is a cross-sectional view of a wafer showing a composite groove according to a modification example. FIG. 16(b) is a cross-sectional view of a wafer showing a composite groove according to a modification example. FIG. 16(c) is a cross-sectional view of a wafer showing a composite groove according to a modification example.

FIG. 17(a) is a cross-sectional view of a wafer showing a composite groove according to a modification example. FIG. 17(b) is a cross-sectional view of a wafer showing a composite groove according to a modification example. FIG. 17(c) is a cross-sectional view of a wafer showing a composite groove according to a modification example.

FIG. 18 is a diagram showing test results for evaluating the deviation of a crack when a composite groove is formed.

FIG. 19(a) is a cross-sectional view of a wafer showing another example of a method for forming a composite groove. FIG. 19(b) is a cross-sectional view of the wafer showing a continuation of FIG. 19(a).

FIG. 20(a) is a cross-sectional view of a wafer showing still another example of the method for forming a composite groove. FIG. 20(b) is a cross-sectional view of the wafer showing a continuation of FIG. 20(a).

FIG. 21 is a flowchart illustrating an example of laser processing including a step of correcting the formation position of a modified region.

FIG. 22 is a perspective view showing a laser processing device in which an optical system for grooving processing and an optical system for forming a modified region are mounted.

FIG. 23(a) is a cross-sectional view of a wafer for explaining a laser processing method according to a modification example. FIG. 23(b) is a cross-sectional view of the wafer showing a continuation of FIG. 23(a). FIG. 23(c) is a cross-sectional view of the wafer showing a continuation of FIG. 23(b).

FIG. 24(a) is a cross-sectional view of the wafer showing a continuation of FIG. 23(c). FIG. 24(b) is a cross-sectional view of the wafer showing a continuation of FIG. 24(a). FIG. 24(c) is a cross-sectional view of the wafer showing a continuation of FIG. 24(b).

FIG. 25 is a cross-sectional view of the wafer showing a continuation of FIG. 24(c).

### DESCRIPTION OF EMBODIMENTS

Hereinafter, an embodiment according to one aspect of the present invention will be described in detail with reference to the diagrams. The same or equivalent portions in the diagrams are denoted by the same reference numerals, and repeated description thereof will be omitted.

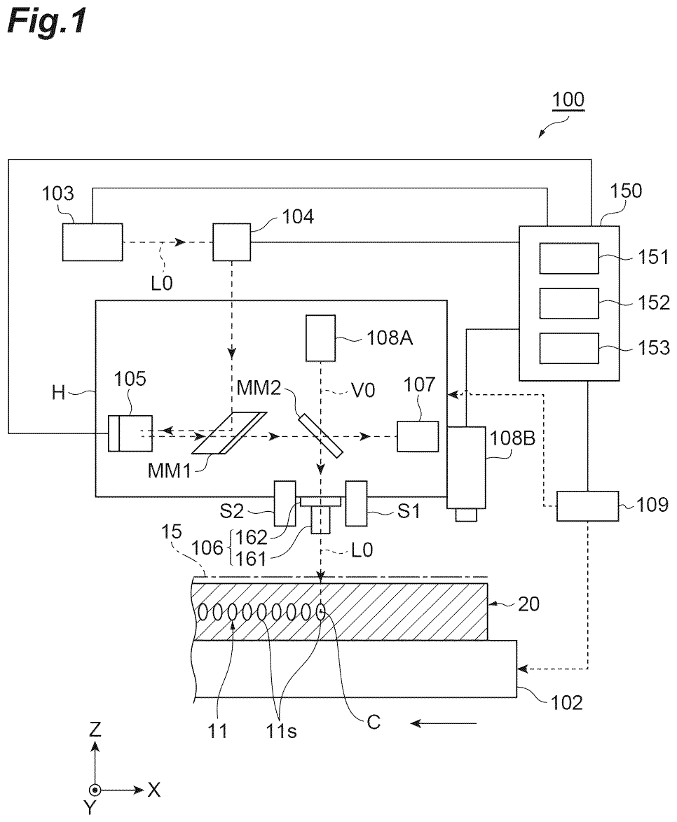

In the present embodiment, a modified region is formed inside a wafer (object). For example, a laser processing device 100 shown in FIG. 1 can be used as a device to form a modified region inside a wafer. As shown in FIG. 1, the laser processing device 100 includes a support unit 102, a light source 103, an optical axis adjustment unit 104, a spatial light modulator 105, a condensing unit 106, an optical axis monitor unit 107, a visible imaging unit 108A, an infrared imaging unit 108B, a moving mechanism 109, and a management unit 150. The laser processing device 100 is a device for forming a modified region 11 on a wafer 20 by irradiating the wafer 20 with laser light L0. In the following description, three directions perpendicular to each other will be referred to as an X direction, a Y direction, and a Z direction. As an example, the X direction is a first horizontal direction, the Y direction is a second horizontal direction perpendicular to the first horizontal direction, and the Z direction is a vertical direction.

The support unit 102 supports the wafer 20, for example, by adsorbing the wafer 20. The support unit 102 is movable along each of the X direction and the Y direction. The support unit 102 is rotatable around a rotation axis along the Z direction. The light source 103 emits the laser light L0 using, for example, a pulse oscillation method. The laser light L0 is transparent to the wafer 20. The optical axis adjustment unit 104 adjusts the optical axis of the laser light L0 emitted from the light source 103. The optical axis adjustment unit 104 is formed by, for example, a plurality of reflecting mirrors whose positions and angles can be adjusted.

The spatial light modulator 105 is disposed inside a laser processing head H. The spatial light modulator 105 modulates the laser light L0 emitted from the light source 103. The spatial light modulator 105 is a spatial light modulator (SLM) of a liquid crystal on silicon (LCOS). In the spatial light modulator 105, the laser light L0 can be modulated by appropriately setting a modulation pattern to be displayed on its display unit (liquid crystal layer). In the present embodiment, the laser light L0 that has traveled downward along the Z direction from the optical axis adjustment unit 104 enters the laser processing head H, is reflected by a mirror MM1, and is incident on the spatial light modulator 105. The spatial light modulator 105 modulates the laser light L0 incident in this manner while reflecting the laser light L0.

The condensing unit 106 is attached to the bottom wall of the laser processing head H. The condensing unit 106 condenses the laser light L0 modulated by the spatial light modulator 105 onto the wafer 20 supported by the support unit 102. In the present embodiment, the laser light L0 reflected by the spatial light modulator 105 is reflected by a dichroic mirror MM2 to be incident on the condensing unit 106. The condensing unit 106 condenses the laser light L0 incident in this manner onto the wafer 20. The condensing unit 106 is formed by attaching a condensing lens unit 161 to the bottom wall of the laser processing head H through a drive mechanism 162. The drive mechanism 162 moves the condensing lens unit 161 along the Z direction, for example, by the driving force of a piezoelectric element.

In addition, in the laser processing head H, an imaging optical system (not shown) is disposed between the spatial light modulator 105 and the condensing unit 106. The imaging optical system forms a double-sided telecentric optical system in which the reflective surface of the spatial light modulator 105 and the entrance pupil plane of the condensing unit 106 are in an imaging relationship. Therefore, the image of the laser light L0 on the reflective surface of the spatial light modulator 105 (image of the laser light L0 modulated by the spatial light modulator 105) is transferred (formed) onto the entrance pupil plane of the condensing unit 106. A pair of ranging sensors S1 and S2 are attached to the bottom wall of the laser processing head H so as to be located on both sides of the condensing lens unit 161 in the X direction. Each of the ranging sensors S1 and S2 acquires displacement data of the laser light incident surface by emitting light for ranging (for example, laser light) to the laser light incident surface of the wafer 20 and detecting the light for ranging reflected from the laser light incident surface.

The optical axis monitor unit 107 is disposed inside the laser processing head H. The optical axis monitor unit 107 detects a part of the laser light L0 transmitted through the dichroic mirror MM2. The detection result of the optical axis monitor unit 107 indicates, for example, a relationship between the optical axis of the laser light L0 incident on the condensing lens unit 161 and the optical axis of the condensing lens unit 161. The visible imaging unit 108A emits visible light V0 and acquires an image of the wafer 20 by the visible light V0 as an image. The visible imaging unit 108A is disposed inside the laser processing head H. The infrared imaging unit 108B emits infrared light and acquires an image of the wafer 20 by the infrared light as an infrared image. The infrared imaging unit 108B is attached to the side wall of the laser processing head H.

The moving mechanism 109 includes a mechanism that moves at least one of the laser processing head H and the support unit 102 in the X direction, the Y direction, and the Z direction. The moving mechanism 109 drives at least one of the laser processing head H and the support unit 102 with the driving force of a known drive device, such as a motor, so that the focusing point C of the laser light L0 moves in the X direction, the Y direction, and the Z direction. The moving mechanism 109 includes a mechanism that rotates the support unit 102. The moving mechanism 109 rotationally drives the support unit 102 with the driving force of a known driving device such as a motor.

The management unit 150 includes a control unit 151, a user interface 152, and a storage unit 153. The control unit 151 controls the operation of each unit of the laser processing device 100. The control unit 151 is configured as a computer device including a processor, a memory, a storage, a communication device, and the like. In the control unit 151, the processor executes software (program) read into the memory or the like to control reading and writing of data in the memory and the storage and communication by the communication device. The user interface 152 displays and inputs various kinds of data. The user interface 152 is a graphical user interface (GUI) having a graphic-based operation system.

The user interface 152 includes, for example, at least one of a touch panel, a keyboard, a mouse, a microphone, a tablet terminal, a monitor, and the like. The user interface 152 can receive various inputs, for example, by touch input, keyboard input, mouse operation, and voice input. The user interface 152 can display various kinds of information on its display screen. The user interface 152 corresponds to an input reception unit that receives an input and a display unit that can display a setting screen based on the received input. The storage unit 153 is, for example, a hard disk, and stores various kinds of data.

In the laser processing device 100 configured as described above, when the laser light L0 is condensed inside the wafer 20, the laser light L is absorbed in a portion corresponding to the focusing point (at least a part of the focusing region) C of the laser light L0, and the modified region 11 is formed inside the wafer 20. The modified region 11 is a region whose density, refractive index, mechanical strength, and other physical properties are different from those of the surrounding non-modified region. Examples of the modified region 11 include a melting treatment region, a crack region, a dielectric breakdown region, and a refractive index change region. The modified region 11 includes a plurality of modified spots 11s and cracks extending from the plurality of modified spots 11s.

As an example, the operation of the laser processing device 100 when forming the modified region 11 inside the wafer 20 along a line 15 for cutting the wafer 20 will be described.

First, the laser processing device 100 rotates the support unit 102 so that the line 15 set on the wafer 20 is parallel to the X direction. The laser processing device 100 moves the support unit 102 along each of the X direction and the Y direction based on the image (for example, an image of the functional element layer included in the wafer 20) acquired by the infrared imaging unit 108B so that the focusing point C of the laser light L0 is located on the line 15 when viewed from the Z direction. The laser processing device 100 moves the laser processing head H (that is, the condensing unit 106) along the Z direction based on the image (for example, an image of the laser light incident surface of the wafer 20) acquired by the visible imaging unit 108A so that the focusing point C of the laser light L0 is located on the laser light incident surface (height set). With the position as a reference, the laser processing device 100 moves the laser processing head H along the Z direction so that the focusing point C of the laser light L0 is located at a predetermined depth from the laser light incident surface.

Subsequently, the laser processing device 100 emits the laser light L0 from the light source 103 and moves the support unit 102 along the X direction so that the focusing point C of the laser light L0 moves relatively along the line 15. At this time, the laser processing device 100 operates the drive mechanism 162 of the condensing unit 106, based on the displacement data of the laser light incident surface acquired by one of the pair of ranging sensors S1 and S2 that is located on the front side in the processing progress direction of the laser light L0, so that the focusing point C of the laser light L0 is located at a predetermined depth from the laser light incident surface.

As a result of the above, a row of modified regions 11 is formed along the line 15 and at a fixed depth from the laser light incident surface of the wafer 20. When the laser light L0 is emitted from the light source 103 using a pulse oscillation method, a plurality of modified spots 11s are formed so as to be aligned in a row along the X direction. One modified spot 11s is formed by the emission of one-pulse laser light L0. The modified regions 11 in one row are a set of a plurality of modified spots 11s arranged in one row. The modified spots 11s adjacent to each other may be connected to each other or separated from each other depending on the pulse pitch of the laser light L0 (a value obtained by dividing the relative moving speed of the focusing point C with respect to the wafer 20 by the repetition frequency of the laser light L0).

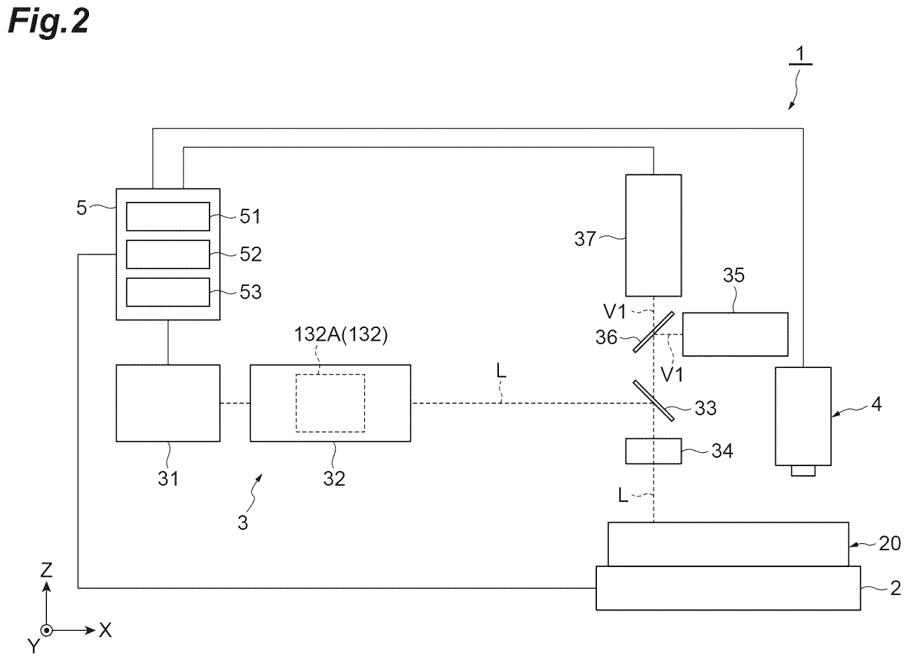

In the present embodiment, grooving processing is performed to form a groove in the wafer 20 along the line 15 by emitting laser light to the street along the line 15 so that the surface layer of the street on the wafer 20 is removed. For example, a laser processing device 1 shown in FIG. 2 can be used as a device to perform grooving processing.

As shown in FIG. 2, the laser processing device 1 includes a support unit 2, an irradiation unit 3, an imaging unit 4, and a control unit 5. The support unit 2 supports the wafer 20. The support unit 2 holds the wafer 20 so that the surface of the wafer 20 including the street faces the irradiation unit 3 and the imaging unit 4, for example, by adsorbing the wafer 20. As an example, the support unit 2 can move along each of the X direction and the Y direction, and can rotate with an axis parallel to the Z direction as a center line.

The irradiation unit 3 irradiates the street of the wafer 20 supported by the support unit 2 with the laser light L. The irradiation unit 3 includes a laser light source 31, a shaping optical system 32, a dichroic mirror 33, and a condensing unit 34. The laser light source 31 emits the laser light L. The shaping optical system 32 adjusts the laser light L emitted from the laser light source 31. The shaping optical system 32 includes a spatial light modulator 132 that modulates the phase of the laser light L.

The spatial light modulator 132 has a display unit 132A on which the laser light L emitted from the laser light source 31 is incident. The spatial light modulator 132 modulates the laser light L according to a modulation pattern displayed on the display unit 132A. The shaping optical system 32 may include an imaging optical system forming a double-sided telecentric optical system in which the modulation surface of the spatial light modulator and the entrance pupil plane of the condensing unit 34 are in an imaging relationship. The shaping optical system 32 may further include an attenuator for adjusting the output of the laser light L and a beam expander for increasing the diameter of the laser light L.

The dichroic mirror 33 reflects the laser light L emitted from the shaping optical system 32 and makes the reflected laser light L incident on the condensing unit 34. The condensing unit 34 condenses the laser light L reflected by the dichroic mirror 33 (the laser light L modulated by the spatial light modulator 132) onto the street of the wafer 20 supported by the support unit 2.

The irradiation unit 3 further includes a light source 35, a half mirror 36, and an imaging element 37. The light source 35 emits the visible light V1. The half mirror 36 reflects the visible light V1 emitted from the light source 35 and makes the reflected visible light V1 incident on the condensing unit 34. The dichroic mirror 33 transmits the visible light V1 between the half mirror 36 and the condensing unit 34. The condensing unit 34 condenses the visible light V1 reflected by the half mirror 36 onto the street of the wafer 20 supported by the support unit 2. The imaging element 37 detects the visible light V1 reflected by the street of the wafer 20 and transmitted through the condensing unit 34, the dichroic mirror 33, and the half mirror 36. In the laser processing device 1, the control unit 5 moves the condensing unit 34 along the Z direction based on the detection result of the imaging element 37, for example, so that the focusing point of the laser light L is located on the street of the wafer 20.

The imaging unit 4 acquires image data of the street of the wafer 20 supported by the support unit 2. The imaging unit 4 is an internal observation camera for observing the inside of the wafer 20 on which the modified region 11 has been formed by the laser processing device 100. The imaging unit 4 emits infrared light to the wafer 20, and acquires an image of the wafer 20 using the infrared light as image data. As the imaging unit 4, an InGaAs camera can be used.

The control unit 5 controls the operation of each unit of the laser processing device 1. The control unit 5 includes a processing unit 51, a storage unit 52, and an input reception unit 53. The processing unit 51 is a computer device including a processor, a memory, a storage, a communication device, and the like. In the processing unit 51, the processor executes software (program) read into the memory or the like to control reading and writing of data in the memory and the storage and communication by the communication device. The storage unit 52 is, for example, a hard disk, and stores various kinds of data. The input reception unit 53 is an interface unit that receives an input of various kinds of data from the operator. As an example, the input reception unit 53 is at least one of a keyboard, a mouse, and a graphical user interface (GUI).

The laser processing device 1 performs grooving processing. In the grooving processing, the control unit 5 controls the irradiation unit 3 so that the laser light L is emitted to each street of the wafer 20 supported by the support unit 2 along the line 15, and the control unit 5 controls the support unit 2 so that the laser light L moves relatively along the line 15 (details will be described later).

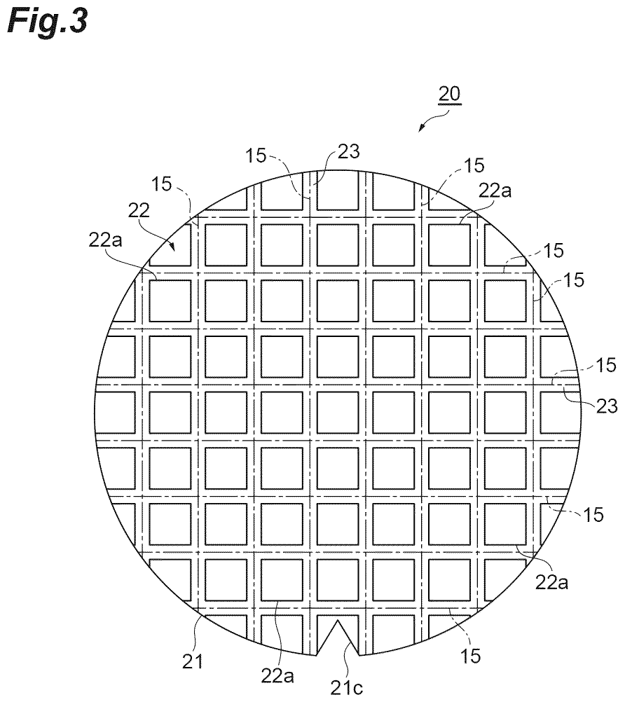

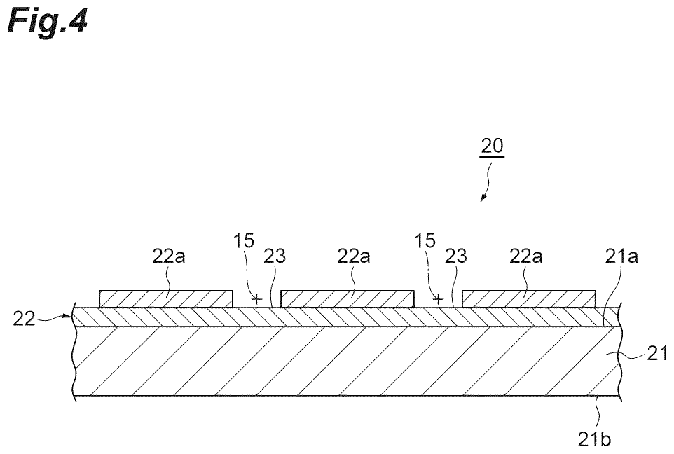

As shown in FIGS. 3 and 4, the wafer 20 includes a semiconductor substrate (substrate) 21 and a functional element layer 22. The thickness of the wafer 20 is, for example, 775 μm. The semiconductor substrate 21 has a front surface 21a and a back surface 21b. The semiconductor substrate 21 is, for example, a silicon substrate. A notch 21c indicating the crystal orientation is provided in the semiconductor substrate 21. Instead of the notch 21c, an orientation flat may be provided in the semiconductor substrate 21. The functional element layer 22 is formed on the front surface 21a of the semiconductor substrate 21. The functional element layer 22 includes a plurality of functional elements 22a. The plurality of functional elements 22a are arranged in a two-dimensional manner along the front surface 21a of the semiconductor substrate 21. Each functional element 22a is, for example, a light receiving element such as a photodiode, a light emitting element such as a laser diode, or a circuit element such as a memory. Each functional element 22a may be formed in a three-dimensional manner by stacking a plurality of layers.

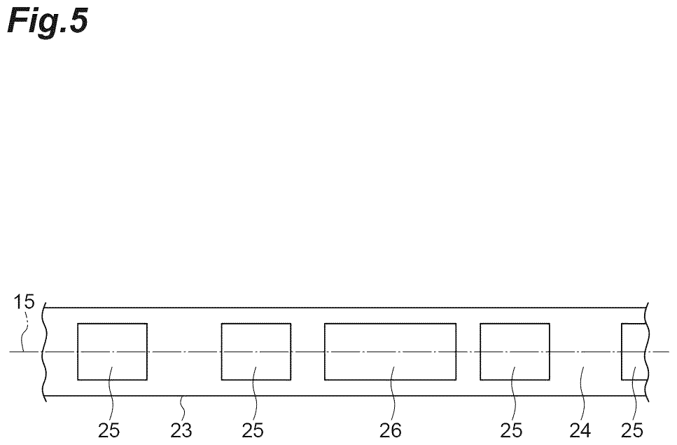

A plurality of streets 23 are formed on the wafer 20. The plurality of streets 23 are regions exposed to the outside between the functional elements 22a adjacent to each other. That is, the plurality of functional elements 22a are arranged adjacent to each other with the street 23 interposed therebetween. As an example, the plurality of streets 23 extend in a lattice shape so as to pass between the adjacent functional elements 22a for the plurality of functional elements 22a arranged in a matrix. As shown in FIG. 5, an insulating film 24 and a plurality of metal structures 25 and 26 are formed on the surface layer of the street 23. The insulating film 24 is, for example, a Low-k film. Each of the metal structures 25 and 26 is, for example, a metal pad. The metal structure 25 and the metal structure 26 are different, for example, in at least one of thickness, area, and material.

As shown in FIGS. 3 and 4, a plurality of lines 15 are set on the wafer 20. The wafer 20 is planned to be cut into the functional elements 22a (that is, to be made into chips corresponding to the respective functional elements 22a) along each of the plurality of lines 15. Each line 15 passes through each street 23 when viewed from the thickness direction of the wafer 20. As an example, each line 15 extends so as to pass through the center of each street 23 when viewed from the thickness direction of the wafer 20. Each line 15 is a virtual line set on the wafer 20 by the laser processing devices 1 and 100. Each line 15 may be a line actually drawn on the wafer 20.

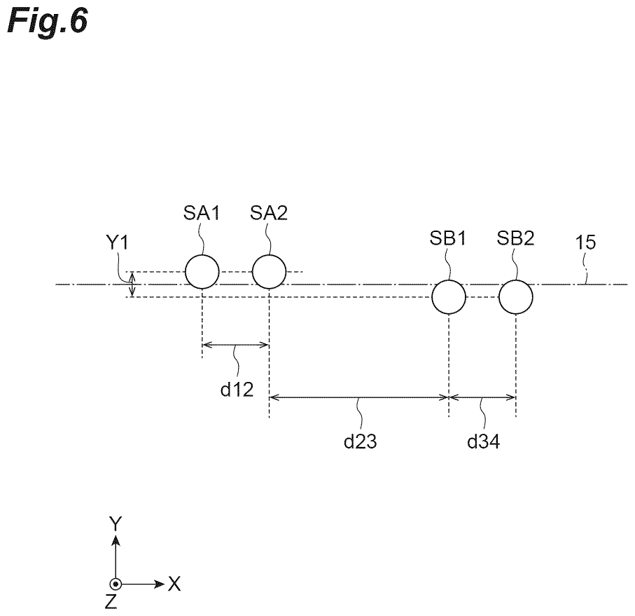

In the present embodiment, the modulation pattern displayed on the display unit 132A of the spatial light modulator 132 includes a branching pattern for branching the laser light L into a plurality (here, two) of first branched laser light components to form a first groove and a plurality (here, two) of second branched laser light components to form a second groove. As shown in FIG. 6, in the present embodiment, focusing points SA1 and SA2 of two first branched laser light components are aligned and then focusing points SB1 and SB2 of two second branched laser light components are aligned from one side of the line 15 toward the other side in the X direction along the line 15. In the Y direction corresponding to the width direction of a groove to be formed, the positions of the focusing points SA1 and SA2 of the first branched laser light components are the same. In the Y direction, the positions of the focusing points SB1 and SB2 of the second branched laser light components are the same.

Each position of the focusing points SA1 and SA2 of the first branched laser light components is also referred to as a first processing point, and each position of the focusing points SB1 and SB2 of the second branched laser light components is also referred to as a second processing point. In the X direction, the distance between the position of the focusing point SA2 of the first branched laser light and the position of the focusing point SB1 of the second branched laser light adjacent to each other is defined as a distance d23. In other words, the distance d23 is a distance in the X direction between the first processing point and the second processing point adjacent to each other. In the Y direction corresponding to the width direction of the groove to be formed, the distance between the positions of the focusing points SA1 and SA2 of the first branched laser light components and the positions of the focusing points SB1 and SB2 of the second branched laser light components is defined as a distance Y1.

The distance d23 is larger than the distance Y1. The distance d23 is larger than the pulse pitch of the laser light L. The distance d23 is, for example, 20 μm or more. The distance d12 between the positions of the focusing points SA1 and SA2 of a plurality of first branched laser light components in the X direction along the line 15 is larger than the pulse pitch of the laser light L. The distance d12 is smaller than the distance d23. The distance d34 between the positions of the focusing points SB1 and SB2 of a plurality of second branched laser light components in the X direction is larger than the pulse pitch of the laser light L. The distance d34 is smaller than the distance d23. The branching pattern branches the laser light L so that the focusing points SA1, SA2, SB1, and SB2 are aligned in a one-dimensional array (including approximately one-dimensional array, substantially one-dimensional array, and about one-dimensional array; the same hereinbelow) along the line 15.

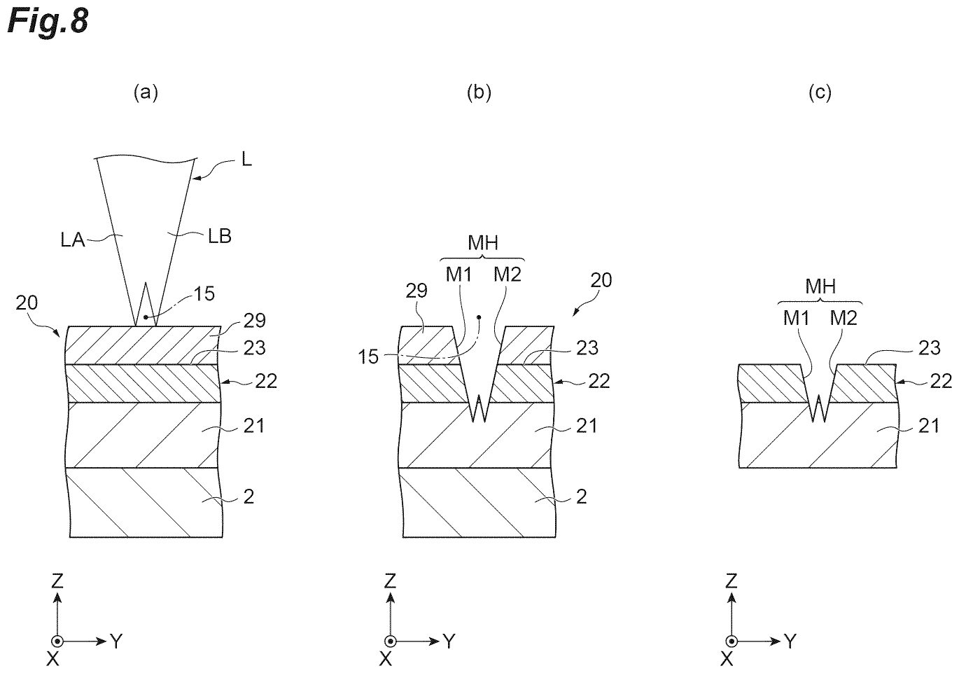

As shown in FIG. 8(b), a first groove M1 formed by first branched laser light LA and a second groove M2 formed by second branched laser light LB form a composite groove MH. The composite groove MH is a W-shaped groove (W-groove) in a cross-sectional view perpendicular to the line 15. The composite groove MH is a groove having a shape having two valley portions and one mountain portion on the bottom side in a cross-sectional view perpendicular to the line 15. Each of the first groove M1 and the second groove M2 is a V-shaped groove (V-groove) in a cross-sectional view perpendicular to the line 15. The second groove M2 overlaps an end portion of the first groove M1 in the Y direction. In other words, the first groove M1 and the second groove M2 extend in the X direction while their end portions in the Y direction overlap each other. The first groove M1 and the second groove M2 are provided so that their peripheral edges are in contact with each other. The first groove M1 and the second groove M2 are grooves having the same depth and width.

The composite groove MH is provided on the functional element layer 22 side of the wafer 20 so that both the bottom of the first groove M1 and the bottom of the second groove M2 reach the semiconductor substrate 21. The bottom of the first groove M1 and the bottom of the second groove M2 reach the functional element layer 22 side of the semiconductor substrate 21. The overlapping end portions of the first groove M1 and the second groove M2 (a mountain portion on the bottom side of the composite groove MH) reach the semiconductor substrate 21 side of the functional element layer 22. The grooving width, which is the grooving width of the composite groove MH on its most open side, is, for example, 12 μm. The grooving width can be input as appropriate through the input reception unit 53 (see FIG. 2). The grooving width is smaller than the width of the street 23.

In addition, the distance d12 and the distance d34 may be the same or may be different. As an example, when the pulse pitch is 0.5 μm, the distance d12 may be 10 μm, the distance d23 may be 20 μm, the distance d34 may be 10 μm, and the distance Y1 may be 5 μm. The distance Y1 is a distance that allows the composite groove MH to have a W shape in cross-sectional view, and may be smaller than the grooving width.

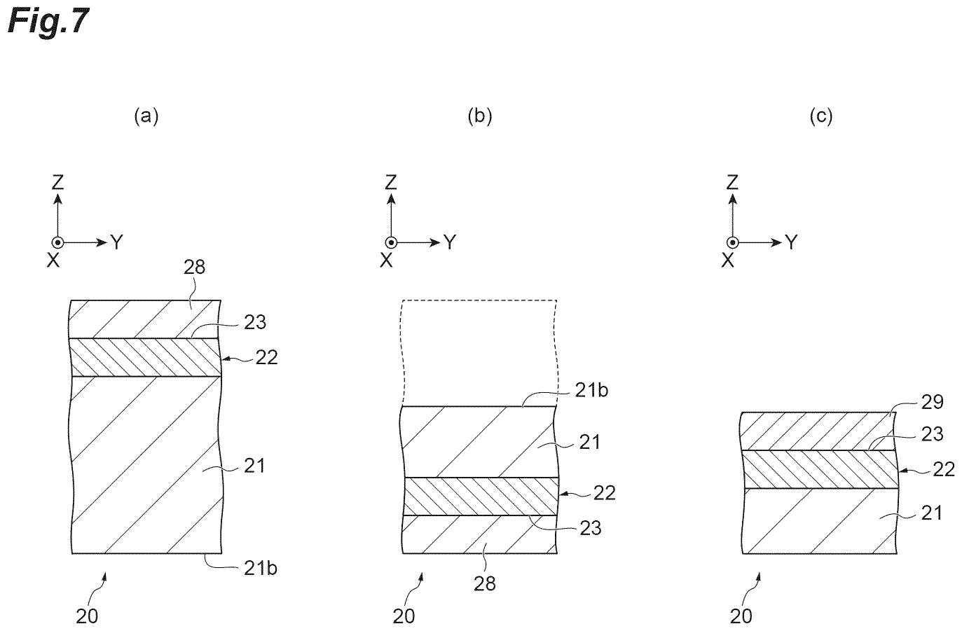

Next, a laser processing method using the laser processing device 100 and the laser processing device 1 will be described with reference to FIGS. 7 to 11.

First, as shown in FIG. 7(a), the wafer 20 is prepared. A grinding tape 28 is attached to the surface of the wafer 20 on the functional element layer 22 side. As shown in FIG. 7(b), the back surface 21b side of the semiconductor substrate 21 of the wafer 20 is ground using a grinding device to make the wafer 20 thin up to a desired thickness (grinding step). As shown in FIG. 7(c), the grinding tape 28 is removed, and a protective film 29 for protecting the functional element layer 22 (functional element 22a) is applied to the surface of the wafer 20 on the functional element layer 22 side.

Subsequently, as shown in FIG. 8(a), in the laser processing device 1, after the wafer 20 is adsorbed and supported by the support unit 2, grooving processing is performed on the wafer 20. In the grooving processing, the control unit 5 controls the irradiation unit 3 so that the laser light L is emitted to the street 23 of the wafer 20 along the line 15, and the control unit 5 controls the support unit 2 so that the laser light L moves relatively along the line 15. As a result, as shown in FIG. 8(b), the surface layer of the street 23 on the wafer 20 is removed to form the composite groove MH including the first groove M1 and the second groove M2.

Specifically, in the grooving processing, the laser light L is emitted, the emitted laser light L is made incident on the display unit 132A (see FIG. 2) of the spatial light modulator 132 (see FIG. 2), the laser light L is branched into the first branched laser light LA and the second branched laser light LB by the modulation pattern displayed on the display unit 132A, and the first branched laser light LA and the second branched laser light LB are condensed onto the wafer 20. In the grooving processing, the condensing unit 34 (see FIG. 2) is moved or modulated by the spatial light modulator 132 so that the first branched laser light LA and the second branched laser light LB are condensed onto the surface of the functional element layer 22 in the Z direction, for example. The first groove M1 is formed by condensing the first branched laser light LA, and the second groove M2 is formed by condensing the second branched laser light LB.

As described above, the modulation pattern includes a branching pattern. The branching pattern can be appropriately generated by the control unit 5 based on the grooving width input through the input reception unit 53 (see FIG. 2). For example, the branching pattern can be automatically generated by the control unit 5 using various known methods so that the focusing points SA1, SA2, SB1, and SB2 of the first branched laser light LA and the second branched laser light LB are located in a one-dimensional array shown in FIG. 6 to realize the composite groove MH having the grooving width.

The processing conditions for forming the composite groove MH are not particularly limited, and can be set based on various known findings. The processing conditions for forming the composite groove MH can be input as appropriate through the input reception unit 53. The processing conditions for forming the composite groove MH may be, for example, the following conditions. In the following example of conditions, burst pulses are not used. However, burst pulses may be used, for example, to suppress film peeling (the same hereinbelow).
Wavelength of laser light L: 515 nm
Pulse width of laser light L: 600 fs
Pulse pitch of laser light L: 0.5 μm
Processing energy (total energy of each focusing point): 4.0 μJ
Number of scans: 1 pass
Position of the bottom of the composite groove MH: 3 μm from the front surface 21a of the semiconductor substrate 21

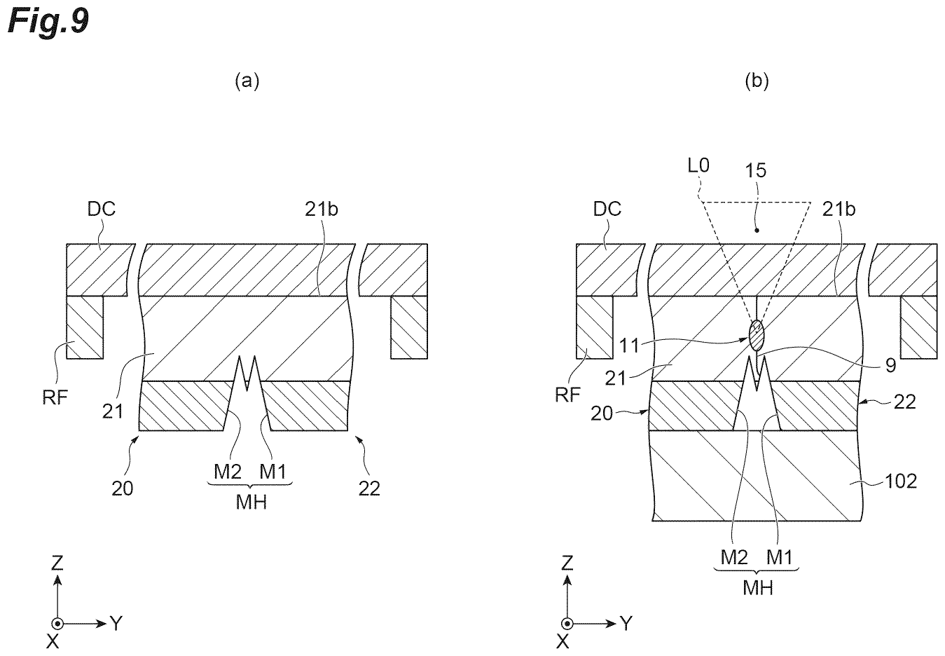

Subsequently, as shown in FIG. 8(c), the wafer 20 is removed from the support unit 2, and the protective film 29 is removed using, for example, a chemical solution. As shown in FIG. 9(a), a transparent dicing tape (tape) DC provided with a ring frame RF is attached to the back surface 21b of the semiconductor substrate 21 of the wafer 20. The transparent dicing tape DC is also called an expand film.

Subsequently, as shown in FIG. 9(b), in the laser processing device 100, the wafer 20 is irradiated with the laser light L0 along the line 15, thereby forming the modified region 11 inside the wafer 20 along the line 15. Here, the wafer 20 is adsorbed and supported by the support unit 102 with the transparent dicing tape DC attached to the back surface 21b of the semiconductor substrate 21, and then the focusing point of the laser light L0 is aligned inside the semiconductor substrate 21 through the transparent dicing tape DC so that the wafer 20 is irradiated with the laser light L0 with the back surface 21b as the laser light incident surface.

The laser light L0 is transparent to the transparent dicing tape DC and the semiconductor substrate 21. When the laser light L0 is condensed inside the semiconductor substrate 21, the laser light L0 is absorbed at a portion corresponding to the focusing point of the laser light L0 and accordingly, the modified region 11 is formed inside the semiconductor substrate 21 and a crack 9 extends from the modified region 11. The processing conditions for forming the modified region 11 are not particularly limited, and can be set based on various known findings. The processing conditions for forming the modified region 11 can be input as appropriate through the user interface 152 (see FIG. 1). The processing conditions for forming the modified region 11 may be, for example, the following conditions.
Wavelength of laser light L0: 1099 nm
Pulse width of laser light L0: 700 nsec
Pulse pitch of laser light L0: 6.5 μm
Processing energy: 22 μJ
Number of scans: 8 passes

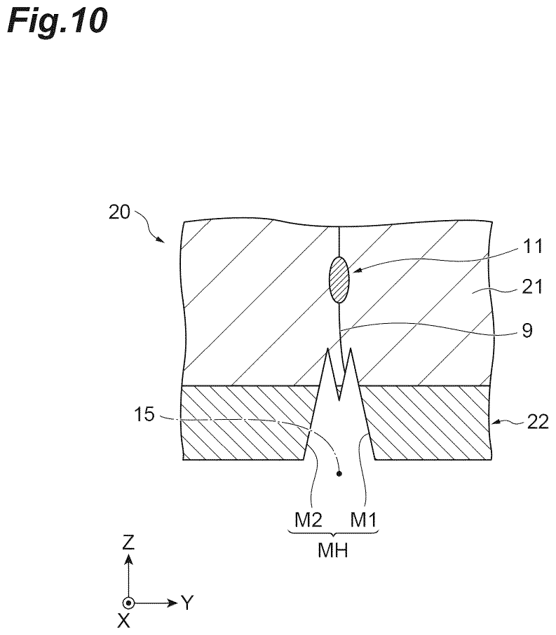

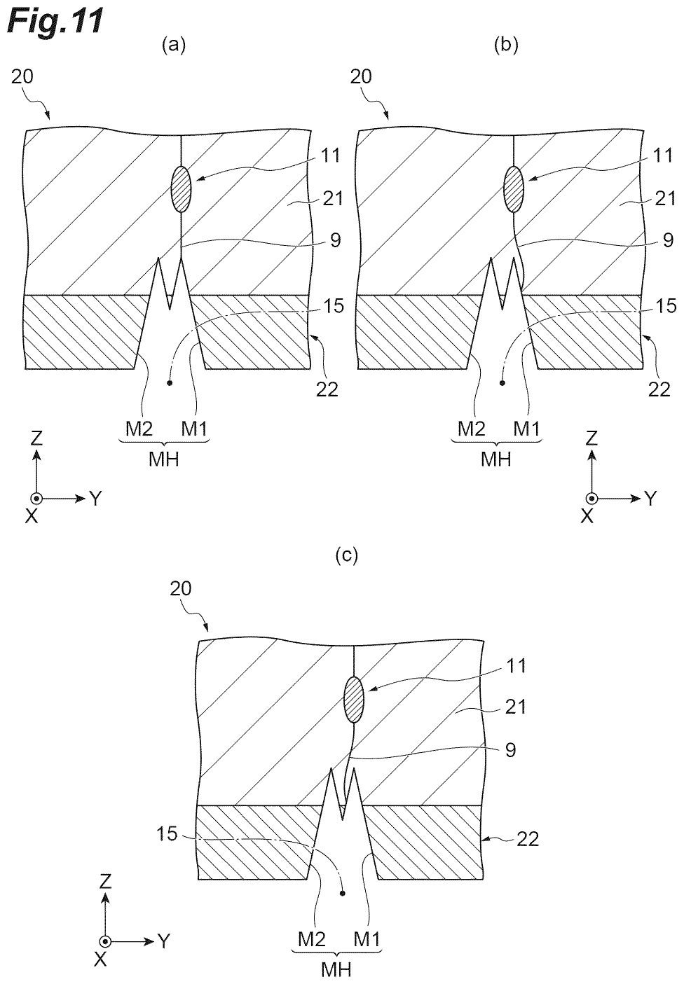

The crack 9 extending from the modified region 11 toward the functional element layer 22 side is induced to extend toward two grooves of the first groove M1 and the second groove M2 of the composite groove MH, and its end reaches the inner surface of the first groove M1 or the inner surface of the second groove M2. For example, in the example shown in FIG. 10, there is substantially no deviation of the modified region 11 from the line 15 in the Y direction, and in this case, the induced crack 9 reaches the inner surface of the first groove M1 on the second groove M2 side. Alternatively, for example, as in the example shown in FIG. 11(a), when there is a deviation of the modified region 11 from the line 15 in the Y direction, the induced crack 9 may reach the bottom of the first groove M1. Alternatively, for example, as in the example shown in FIG. 11(b), when there is a deviation of the modified region 11 from the line 15 in the Y direction, the induced crack 9 may reach the inner surface of the first groove M1 on a side opposite to the second groove side. Alternatively, for example, as in the example shown in FIG. 11(c), when there is a deviation of the modified region 11 from the line 15 in the Y direction, the induced crack 9 may reach the inner surface of the first groove M1 on the second groove M2 side.

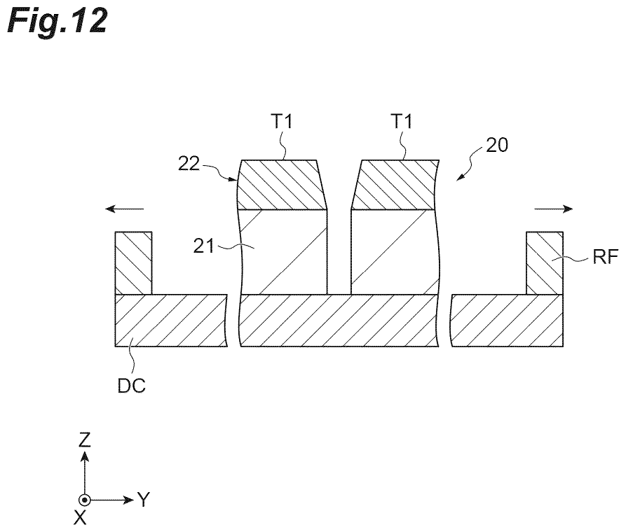

Subsequently, as shown in FIG. 12, by expanding the attached transparent dicing tape DC with an expander (not shown), the crack is extended in the thickness direction of the wafer 20 from the modified region 11 formed inside the semiconductor substrate 21 along each line 15, thereby cutting the wafer 20 along the line 15. As a result, the wafer 20 is made into chips corresponding to the respective functional elements 22a, and a plurality of chips Tl are obtained.

In the above, for example, instead of the transparent dicing tape DC, a protective tape may be attached to the functional element layer 22 side, and the laser light L0 may be emitted from the back surface 21b of the semiconductor substrate 21 to form the modified region 11. Then, the transparent dicing tape DC may be attached to the back surface 21b side of the semiconductor substrate 21 and the protective tape on the functional element layer 22 side may be peeled off, and then the transparent dicing tape DC may be expanded and divided. For example, using a support material, laser processing (grooving processing and formation of the modified region 11) may be performed with a protective film attached. Then, the protective film may be removed, the transparent dicing tape DC may be attached, and the transparent dicing tape DC may be expanded and divided.

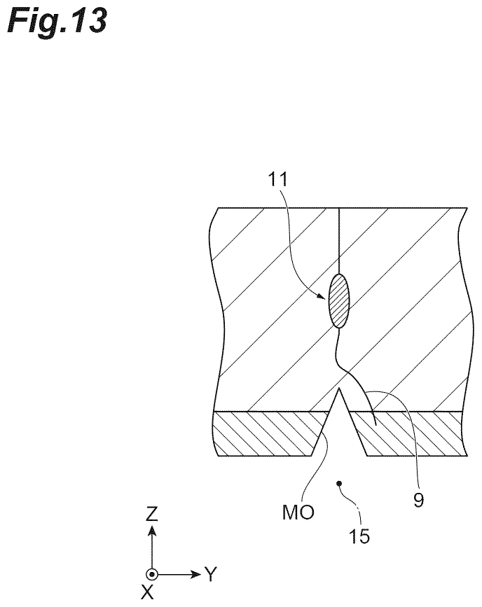

Incidentally, as shown in FIG. 13, when forming a single V-groove M0 in the wafer 20 along the line 15, the crack 9 from the modified region 11 formed further inward than the V-groove M0 in the Z direction in the wafer 20 tends to extend so as to deviate from the V-groove M0. For this reason, the crack 9 deviates significantly from the line 15. In this case, the cutting quality when cutting the wafer 20 deteriorates. This increases the possibility of deterioration of dividing quality, occurrence of tearing, and remaining cracks.

In this regard, in the present embodiment, the composite groove MH including the first groove M1 and the second groove M2 whose end portions overlap each other is formed in the wafer 20. Therefore, since the crack 9 is induced to extend toward two grooves of the first groove M1 and the second groove M2 while suppressing the grooving width from increasing, the effect of inducing the crack 9 can be increased compared with a case where the single V-groove M0 is formed. As a result, it is possible to suppress the crack 9 from extending in a deviating manner. That is, it is possible to suppress the deviation of the crack 9 extending from the modified region 11 while reducing the grooving width. The deviation of the crack 9 can be kept within the grooving width. Since it is possible to improve the dividing quality, all the chips can be reliably divided. The width of the street 23 can be reduced.

The present embodiment further includes a step of cutting the wafer 20 along the line 15 by expanding the transparent dicing tape DC attached to the wafer 20 with the end of the crack 9 reaching the inner surface of the first groove M1 or the inner surface of the second groove M2 after forming the modified region 11. In this case, it is possible to accurately cut the wafer 20 along the line 15.

In the present embodiment, the wafer 20 has the semiconductor substrate 21 and the functional element layer 22. The composite groove MH is provided on the functional element layer 22 side of the wafer 20 so that both the bottom of the first groove M1 and the bottom of the second groove M2 reach the semiconductor substrate 21. In this case, it is possible to further enhance the effect of inducing the crack 9 by the first groove M1 and the second groove M2.

The present embodiment includes a step of forming the protective film 29 on the functional element layer 22 before forming the composite groove MH. In this case, the functional element layer 22 can be effectively protected by the protective film 29. In the present embodiment, the composite groove MH has a W shape in a cross-sectional view perpendicular to the line 15. In this case, the above-described effect of suppressing the deviation of the crack 9 while reducing the grooving width becomes noticeable. The present embodiment includes a step of grinding the wafer 20 to make the wafer 20 thin before forming the composite groove MH. In this case, the wafer 20 can be made thin by grinding before forming the composite groove MH.

Here, in the laser processing device 1 and the laser processing method according to the present embodiment, the distance d23 between the first processing point and the second processing point adjacent to each other (the position of the focusing point SA2 of the first branched laser light and the position of the focusing point SB1 of the second branched laser light) in the X direction is larger than the distance Y1 between the first processing position and the second processing position in the Y direction. This makes it possible to separate the first processing point and the second processing point from each other until the first processing point and the second processing point hardly influence each other. Examples of the influence include interference with the preceding processing point and the influence of processing in a heat-affected state. In addition, it is possible to separate the first processing point and the second processing point from each other until the influence substantially disappears. As a result, each of the first groove M1 and the second groove M2 can be reliably formed as independent grooves in the wafer 20. The first groove M1 and the second groove M2 can be firmly formed so that their bottoms are clearly formed. Therefore, with the laser processing device 1 and the laser processing method for branching the laser light L into a plurality of branched laser light components and irradiating the wafer 20 with the branched laser light components, it is possible to form the first groove M1 and the second groove M2 satisfactorily in the wafer 20 along the line 15.

In the present embodiment, the second groove M2 overlaps the end portion of the first groove M1 in the width direction of the first groove M1. The composite groove MH including the first groove M1 and the second groove M2 can be formed in the wafer 20. Such a composite groove MH can effectively induce the crack 9 extending from the modified region 11 formed inside the wafer 20, for example.

In the present embodiment, the distance d23 in the X direction is larger than the pulse pitch of the laser light L. In this case, since the occurrence of a situation in which the distance between the first processing position and the second processing position is too short and accordingly their influence on each other becomes significant is suppressed, it is possible to form the first groove M1 and the second groove M2 satisfactorily in the wafer 20.

In the present embodiment, the distance d12 between a plurality of first processing positions in the X direction is larger than the pulse pitch of the laser light L. In this case, since it is possible to suppress the occurrence of a situation in which the distance d12 between the plurality of first processing positions is too short and accordingly their influence on each other becomes significant, it is possible to form the first groove M1 satisfactorily.

In the present embodiment, the distance d12 between the plurality of first processing positions in the X direction is smaller than the distance d23. In this case, the distance between the plurality of first processing positions can be set to a range where they influence each other so that a HAZ (Heat-Affected-Zone) generated around the formed first groove M1 can be suppressed.

In the present embodiment, the distance d34 between a plurality of second processing positions in the X direction is larger than the pulse pitch of the laser light L. In this case, since it is possible to suppress the occurrence of a situation in which the distance between the plurality of second processing positions is too short and accordingly their influence on each other becomes significant, it is possible to form the second groove M2 satisfactorily.

In the present embodiment, the distance d34 between the plurality of second processing positions in the X direction is smaller than the distance d23. In this case, the distance between the plurality of second processing positions can be set to a range where they influence each other so that the HAZ generated around the formed second groove M2 can be suppressed.

In the present embodiment, the branching pattern branches the laser light L into two first branched laser light components LA and two second branched laser light components LB. In this case, since the energy at each of the focusing points SA1, SA2, SB1, and SB2 can be reduced, the HAZ can be suppressed.

In the present embodiment, the branching pattern branches the laser light L so that the focusing points SA1, SA2, SB1, and SB2 are aligned in a one-dimensional array along the line 15. Therefore, it is possible to form the narrow composite groove MH in the wafer 20. In addition, the flexural strength of the wafer 20 can be improved.

Even if there is no deviation in the position of the modified region 11 from the position of the line 15 in the Y direction, when forming a single V-groove M0, a problem may occur as a result of the meandering of the crack 9 extending from the modified region 11. In this regard, in the present embodiment, since the composite groove MH is formed as a W-groove, the problem can be suppressed.

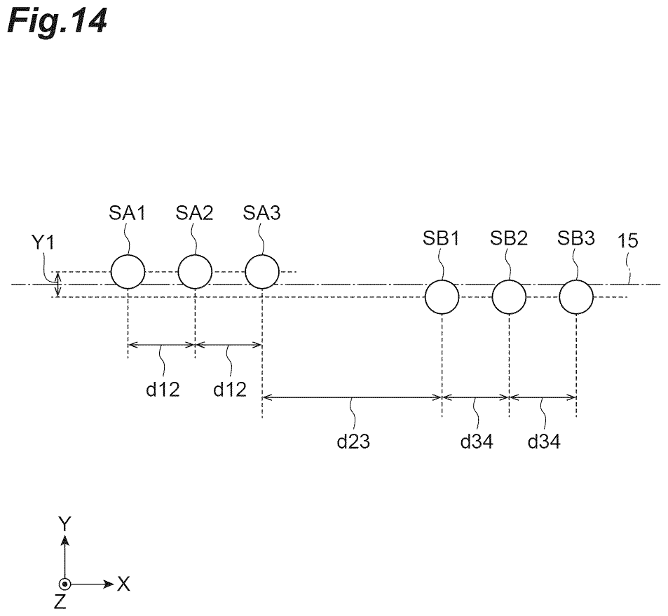

In addition, in the present embodiment, the branching pattern may branch the laser light L into three first branched laser light components LA forming the first groove M1 and three second branched laser light components LB forming the second groove M2. In this case, for example, as shown in FIG. 14, in the X direction along the line 15 from one side of the line 15 toward the other side, the focusing points SA1, SA2, and SA3 of the three first branched laser light components are aligned and then the focusing points SB1, SB2, and SB3 of the three second branched laser light components are aligned. In the Y direction corresponding to the width direction of a groove to be formed, the positions of the focusing points SA1, SA2, and SA3 of the first branched laser light components are the same. In the Y direction, the positions of the focusing points SB1, SB2, and SB3 of the second branched laser light components are the same. According to such a branching pattern, since the energy at each of the focusing points SA1, SA2, SA3, SB1, SB2, and SB3 can be further reduced, the HAZ can be further suppressed.

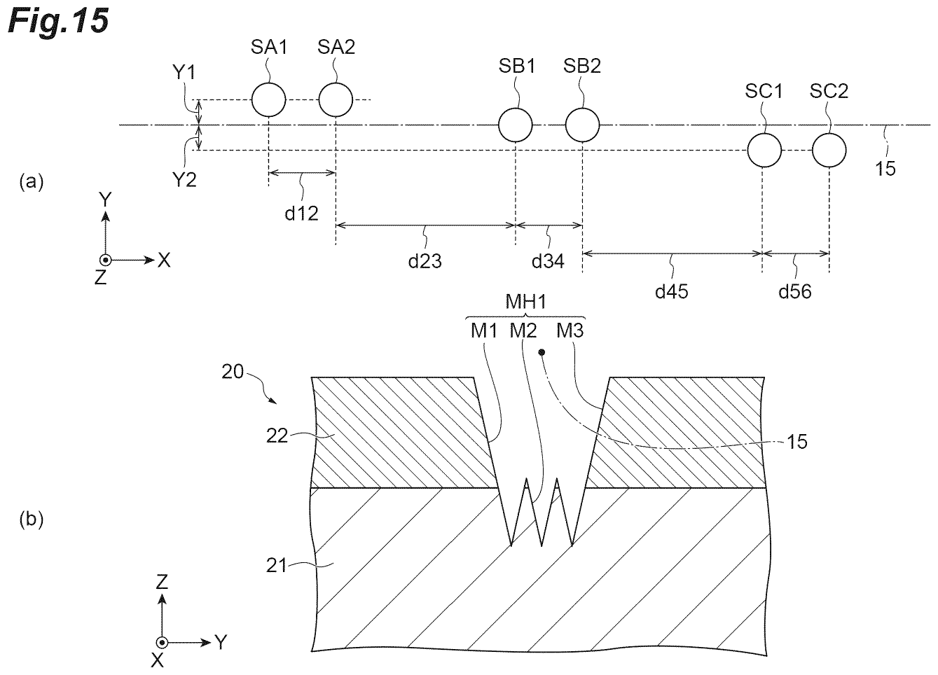

In the present embodiment, the branching pattern displayed on the display unit 132A of the spatial light modulator 132 may branch the laser light L into one or more (here, two) first branched laser light components LA to form the first groove M1, one or more (here, two) second branched laser light components LB to form the second groove M2, and one or more (here, two) third branched laser light components to form the third groove M3. In this case, for example, as shown in FIG. 15(a), in the X direction along the line 15 from one side of the line 15 toward the other side, the focusing points SA1 and SA2 of the two first branched laser light components are aligned, the focusing points SB1 and SB2 of the two second branched laser light components are aligned, and then the focusing points SC1 and SC2 of the two third branched laser light components are aligned. In the Y direction corresponding to the width direction of a groove to be formed, the positions of the focusing points SC1 and SC2 of the third branched laser light components are the same.

In the X direction, the distance between the position of the focusing point SB2 of the second branched laser light and the position of the focusing point SC1 of the third branched laser light adjacent to each other is defined as a distance d45. The distance d45 is equal to the distance d23. In the Y direction, the distance between each of the positions of the focusing points SB1 and SB2 of the second branched laser light components and each of the positions of the focusing points SC1 and SC2 of the third branched laser light components is defined as a distance Y2. The distance Y2 is equal to the distance Y1. The distance d45 is larger than the distance Y1. The distance d45 is larger than the pulse pitch of the laser light L. The distance d56 between the positions of the focusing points SC1 and SC2 of a plurality of third branched laser light components in the X direction along the line 15 is larger than the pulse pitch of the laser light L. The distance d56 is smaller than the distance d23. The branching pattern branches the laser light L so that the focusing points SA1, SA2, SB1, SB2, SC1, and SC2 are aligned in a one-dimensional array along the line 15. In this case, as shown in FIG. 15(b), it is possible to form a wide composite groove MH1.

The first groove M1 formed by the first branched laser light LA, the second groove M2 formed by the second branched laser light LB, and the third groove M3 formed by the third branched laser light form the composite groove MH1. The composite groove MH1 is a groove having a shape having three valley portions and two mountain portions on the bottom side in a cross-sectional view perpendicular to the line 15. Each of the first groove M1, the second groove M2, and the third groove M3 is a V-groove in a cross-sectional view perpendicular to the line 15. The second groove M2 overlaps an end portion of the first groove M1 in the Y direction. In other words, the first groove M1 and the second groove M2 extend in the X direction while their end portions in the Y direction overlap each other. The first groove M1 and the second groove M2 are provided so that their peripheral edges are in contact with each other. An end portion of the third groove M3 in the Y direction overlaps an end portion of the second groove M2 in the Y direction. In other words, the second groove M2 and the third groove M3 extend in the X direction while their end portions in the Y direction overlap each other. The second groove M2 and the third groove M3 are provided so that their peripheral edges are in contact with each other. The first groove M1, the second groove M2, and the third groove M3 are grooves having the same depth and width.

The composite groove MH1 is provided on the functional element layer 22 side of the wafer 20 so that the bottom of the first groove M1, the bottom of the second groove M2, and the bottom of the third groove M3 all reach the semiconductor substrate 21. The bottom of the first groove M1 and the bottom of the second groove M2 reach the functional element layer 22 side of the semiconductor substrate 21. The overlapping end portions of the first groove M1, the second groove M2, and the third groove M3 (two mountain portions on the bottom side of the composite groove MH1) reach the semiconductor substrate 21 side of the functional element layer 22.

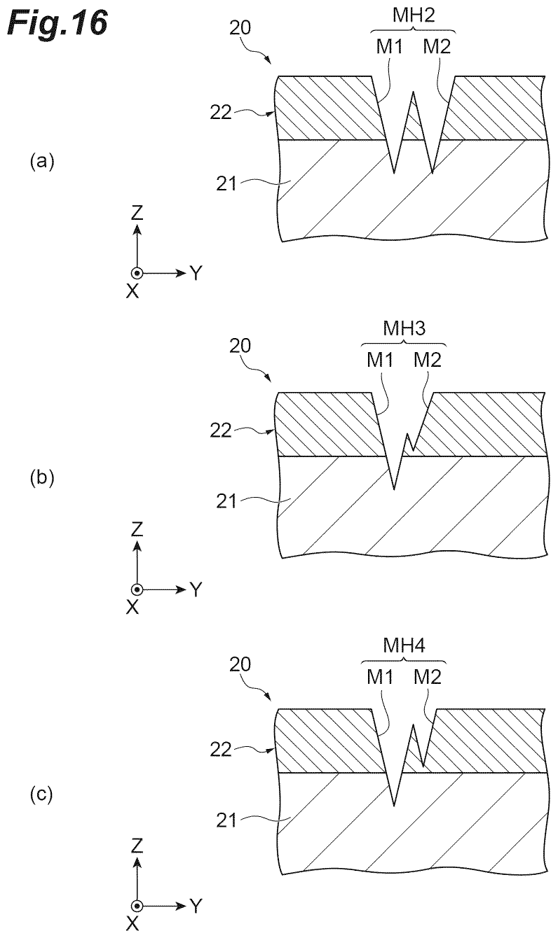

Incidentally, in the present embodiment, as shown in FIG. 16(a), a composite groove MH2 may be provided on the functional element layer 22 side of the wafer 20. The composite groove MH2 is a W-groove formed by the first groove M1 and the second groove M2. The second groove M2 overlaps an end portion of the first groove M1 in the Y direction. The composite groove MH2 is provided so that both the bottom of the first groove M1 and the bottom of the second groove M2 reach the semiconductor substrate 21. The overlapping end portions of the first groove M1 and the second groove M2 (a mountain portion on the bottom side of the composite groove MH) reach the semiconductor substrate 21 side of the functional element layer 22. The bottoms of the first groove M1 and the second groove M2 of the composite groove MH2 are separated from each other in the Y direction compared with the composite groove MH (see FIG. 8(b)). Even with such a composite groove MH2, the same effect as in the case of the composite groove MH is achieved.

In the present embodiment, as shown in FIG. 16(b), a composite groove MH3 may be provided on the functional element layer 22 side of the wafer 20. The composite groove MH3 is a W-groove formed by the first groove M1 and the second groove M2. The second groove M2 overlaps an end portion of the first groove M1 in the Y direction. The first groove M1 is a groove deeper than the second groove M2. The composite groove MH3 is provided so that the bottom of the first groove M1 reaches the semiconductor substrate 21 and the bottom of the second groove M2 does not reach the semiconductor substrate 21. That is, either the bottom of the first groove M1 or the bottom of the second groove M2 is provided so as to reach the semiconductor substrate 21. The overlapping end portions of the first groove M1 and the second groove M2 (a mountain portion on the bottom side of the composite groove MH3) reach the semiconductor substrate 21 side of the functional element layer 22. Even with such a composite groove MH3, the same effect as in the case of the composite groove MH is achieved. It is possible to further enhance the effect of inducing the crack 9 by the first groove M1 and the second groove M2.

In the present embodiment, as shown in FIG. 16(c), a composite groove MH4 may be provided on the functional element layer 22 side of the wafer 20. The composite groove MH4 is a W-groove formed by the first groove M1 and the second groove M2. The second groove M2 overlaps an end portion of the first groove M1 in the Y direction. The first groove M1 is a groove deeper than the second groove M2. The composite groove MH4 is provided so that the bottom of the first groove M1 reaches the semiconductor substrate 21 and the bottom of the second groove M2 does not reach the semiconductor substrate 21. That is, either the bottom of the first groove M1 or the bottom of the second groove M2 is provided so as to reach the semiconductor substrate 21. The overlapping end portions of the first groove M1 and the second groove M2 (a mountain portion on the bottom side of the composite groove MH4) reach the surface side of the functional element layer 22. The bottoms of the first groove M1 and the second groove M2 of the composite groove MH4 are separated from each other in the Y direction compared with the composite groove MH3 (see FIG. 16(b)). Even with such a composite groove MH4, the same effect as in the case of the composite groove MH is achieved. It is possible to further enhance the effect of inducing the crack 9 by the first groove M1 and the second groove M2.

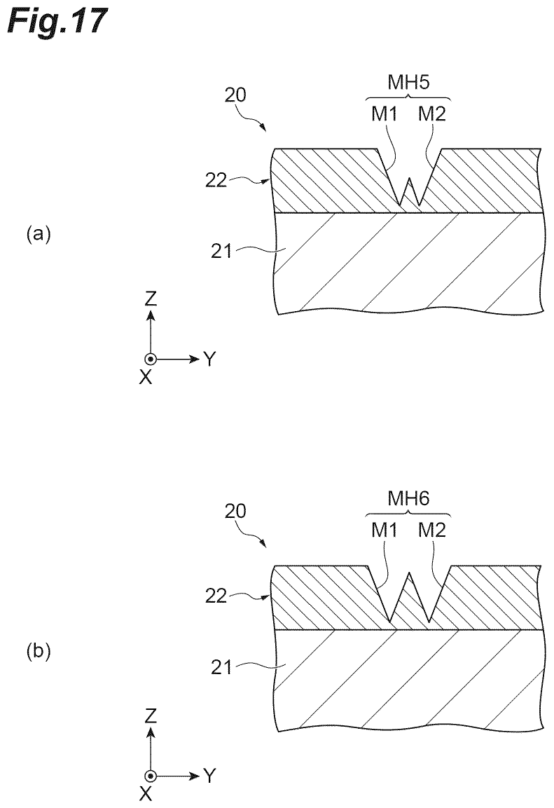

In the present embodiment, as shown in FIG. 17(a), a composite groove MH5 may be provided on the functional element layer 22 side of the wafer 20. The composite groove MH5 is a W-groove formed by the first groove M1 and the second groove M2. The second groove M2 overlaps an end portion of the first groove M1 in the Y direction. The first groove M1 and the second groove M2 are grooves having the same depth and width. The composite groove MH2 is provided so that both the bottom of the first groove M1 and the bottom of the second groove M2 do not reach the semiconductor substrate 21. Even with such a composite groove MH5, the same effect as in the case of the composite groove MH is achieved. It is possible to reduce the depths of the first groove M1 and the second groove M2.

In the present embodiment, as shown in FIG. 17(b), a composite groove MH6 may be provided on the functional element layer 22 side of the wafer 20. The composite groove MH6 is a W-groove formed by the first groove M1 and the second groove M2. The second groove M2 overlaps an end portion of the first groove M1 in the Y direction. The first groove M1 and the second groove M2 are grooves having the same depth and width. The composite groove MH6 is provided so that both the bottom of the first groove M1 and the bottom of the second groove M2 do not reach the semiconductor substrate 21. The overlapping end portions of the first groove M1 and the second groove M2 (a mountain portion on the bottom side of the composite groove MH6) reach the surface side of the functional element layer 22. The bottoms of the first groove M1 and the second groove M2 of the composite groove MH6 are separated from each other in the Y direction compared with the composite groove MH5 (see FIG. 17(a)). Even with such a composite groove MH6, the same effect as in the case of the composite groove MH is achieved. It is possible to further enhance the effect of inducing the crack 9 by the first groove M1 and the second groove M2.

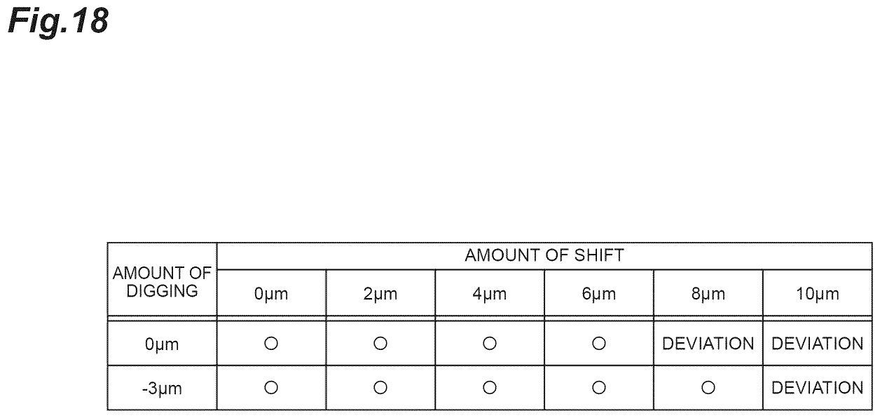

FIG. 18 is a diagram showing the test results for evaluating the deviation of the crack 9 when the composite groove MH is formed. In the diagram, the amount of digging is the position of the bottom of the composite groove MH, and is the amount of entering the semiconductor substrate 21 from the front surface 21a of the semiconductor substrate 21. The amount of shift corresponds to the amount of deviation between the formed modified region 11 and the center of the composite groove MH in the width direction of the composite groove MH. “O” means that the end of the crack 9 is induced to reach the inner surface of the first groove M1 or the inner surface of the second groove M2. “Deviation” means that the crack 9 deviates from the composite groove MH and the end of the crack 9 does not reach the inner surface of the first groove M1 or the inner surface of the second groove M2. In the test shown in the diagram, the grooving width is 12 μm. As shown in FIG. 18, according to the composite groove MH, it can be seen that, even if the formed modified region 11 deviates from the composite groove MH in the width direction, the effect of inducing the crack 9 can be obtained as long as the amount of deviation falls within a predetermined range. In addition, it can be seen that the larger the amount of digging, the more effectively the effect of inducing the crack 9 with respect to the amount of shift can be achieved.

In the grooving processing of the present embodiment, the first groove M1 and the second groove M2 are formed simultaneously by the first branched laser light LA and the second branched laser light LB, which are formed by branching the laser light L with the branching pattern displayed on the display unit 132A of the spatial light modulator 132. However, the present invention is not limited thereto. The grooving processing may include a step of forming the first groove M1 in the wafer 20 along the line 15 by irradiating the wafer 20 with the laser light L and a step of forming the second groove M2 in the wafer 20 along the line 15 by irradiating the wafer 20 with the laser light L.

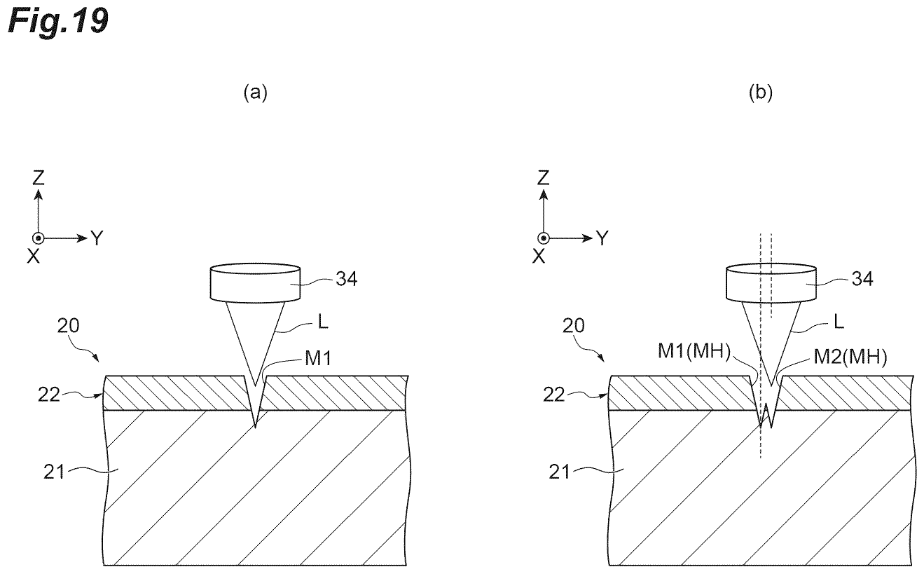

For example, as shown in FIG. 19(a), the surface layer of the wafer 20 on the functional element layer 22 side is removed by condensing the laser light L onto the functional element layer 22 through the condensing unit 34, thereby forming the first groove M1. Thereafter, as shown in FIG. 19(b), the surface layer of the wafer 20 on the functional element layer 22 side may be removed by moving at least one of the condensing unit 34 and the support unit 2 (see FIG. 2) by a predetermined amount in the Y direction (width direction of the first groove M1) and condensing the laser light L onto the functional element layer 22 through the condensing unit 34, thereby forming the second groove M2.

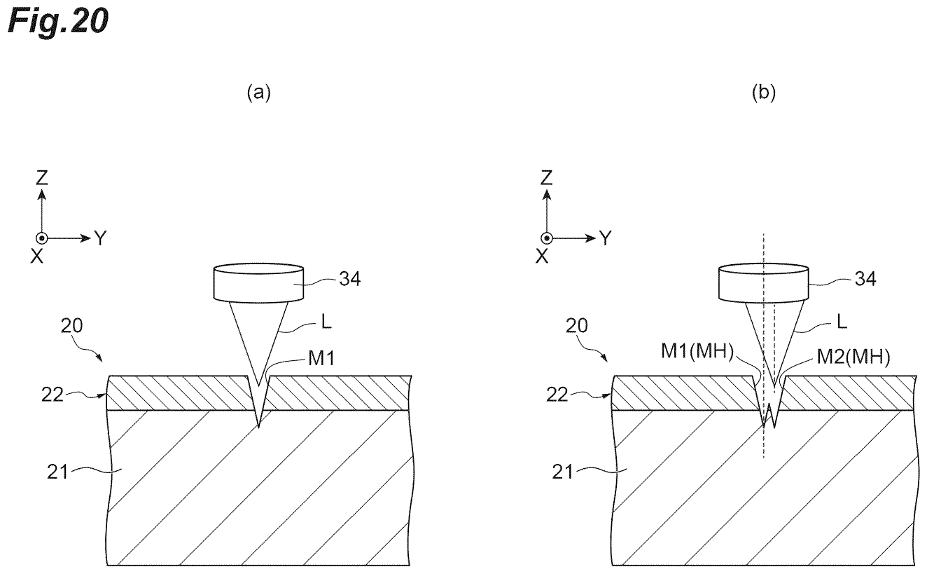

In addition, for example, as shown in FIG. 20(a), the surface layer of the wafer 20 on the functional element layer 22 side is removed by condensing the laser light L onto the functional element layer 22 through the condensing unit 34, thereby forming the first groove M1. Thereafter, the surface layer of the wafer 20 on the functional element layer 22 side may be removed by displaying a shift pattern on the display unit 132A of the spatial light modulator 132 to shift the focusing point of the laser light L by a predetermined amount in the Y direction (width direction of the first groove M1) and condensing the laser light L onto the functional element layer 22 through the condensing unit 34 as shown in FIG. 20(b), thereby forming the second groove M2.

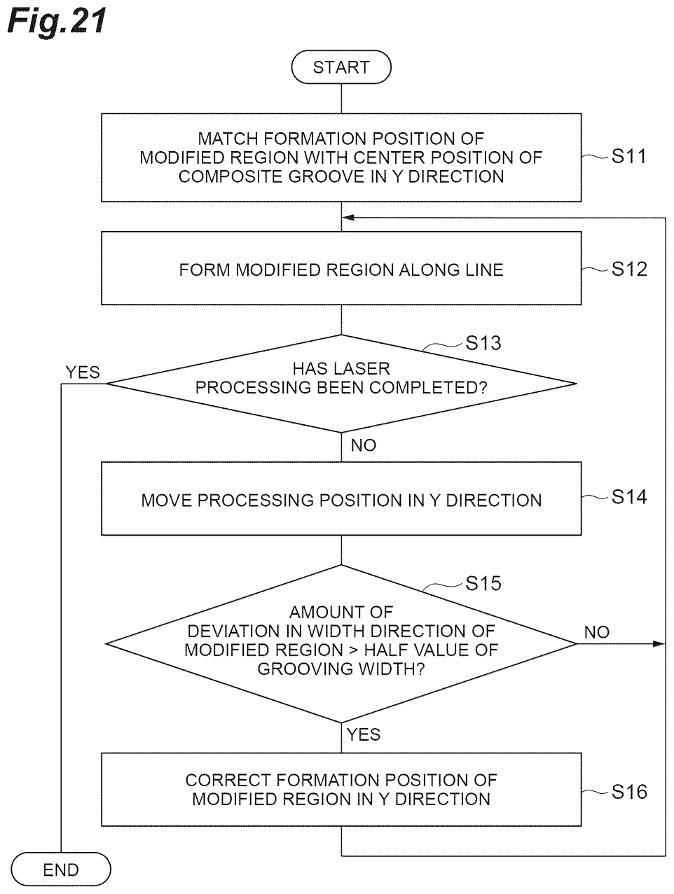

In the present embodiment, the step of forming the modified region 11 may include a step of correcting the formation position of the modified region 11 so as to match the center position when the amount of deviation (hereinafter referred to as “width direction deviation amount”) of the formation position of the modified region 11 from the center position of the composite groove MH in the width direction of the composite groove MH is larger than the half value of the grooving width. As an example, for example, the following steps shown in FIG. 21 may be included.

In the step of forming the modified region 11, first, in the Y direction corresponding to the width direction of the composite groove MH, the formation position of the modified region 11 (position where the modified region 11 is planned to be formed) is made to match the center position of the composite groove MH, which is a reference processing position (step S11). The center position of the composite groove MH can be checked based on an image captured by the infrared imaging unit 108B, for example (see FIG. 1). Subsequently, the modified region 11 is formed along the line 15 as described above (step S12).

When the formation of the modified region 11 along the entire line 15 extending in the X direction is completed (YES in step S13), it is determined that the laser processing has been completed and the processing is terminated, and the process proceeds to the next step. On the other hand, when the formation of the modified region 11 along the entire line 15 extending in the X direction is not completed (NO in step S13), the formation position of the modified region 11 is moved by a predetermined distance (distance corresponding to the distance between the two lines 15 adjacent to each other) in the Y direction, and at least one of the laser processing head H and the support unit 102 (see FIG. 1) is moved in the Y direction (step S14).

It is determined whether or not the amount of deviation in the width direction of the modified region 11 is larger than the half value (½ value) of the grooving width (step S15). The amount of deviation in the width direction of the modified region 11 can be checked based on an image captured by the infrared imaging unit 108B, for example (see FIG. 1). If YES in step S15 above, the formation position of the modified region 11 in the Y direction is corrected (step S16). In step S16 above, the position of at least one of the laser processing head H and the support unit 102 (see FIG. 1) is adjusted in the Y direction so that the formation position of the modified region 11 matches the center position of the composite groove MH in the Y direction. If NO in step S15 above or after step S16 above, the process returns to the processing of step S12. According to the laser processing method according to the above modification example, it is possible to correct the formation position of the modified region 11 by using the grooving width.

### Modification Examples

One aspect of the present invention is not limited to the embodiment described above.

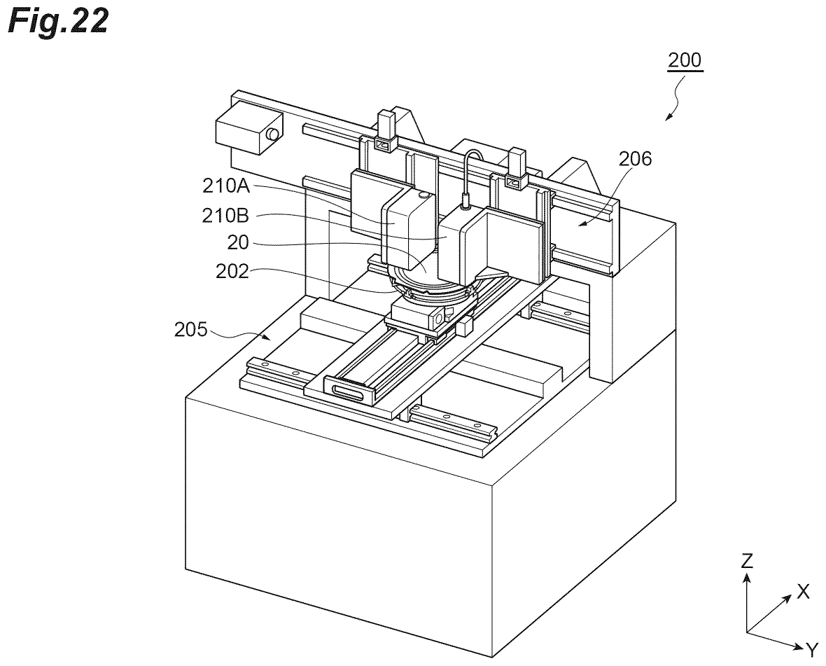

In the embodiment described above, the laser processing device 1 to perform grooving processing and the laser processing device 100 to form the modified region 11 inside the wafer 20 are separate devices, but the present invention is not limited thereto. For example, a device for grooving processing and a device for forming the modified region 11 may be integrated by being connected to each other by a transfer arm. As an example, like a laser processing device 200 shown in FIG. 22, a stage 202 may be used in common to mount an optical system 210A corresponding to a processing device for grooving processing and an optical system 210B corresponding to a processing device for forming the modified region 11. In addition, such a laser processing device 200 includes a moving mechanism 205 to move the stage (support unit) 202 and a moving mechanism 206 to move the optical systems 210A and 210B.

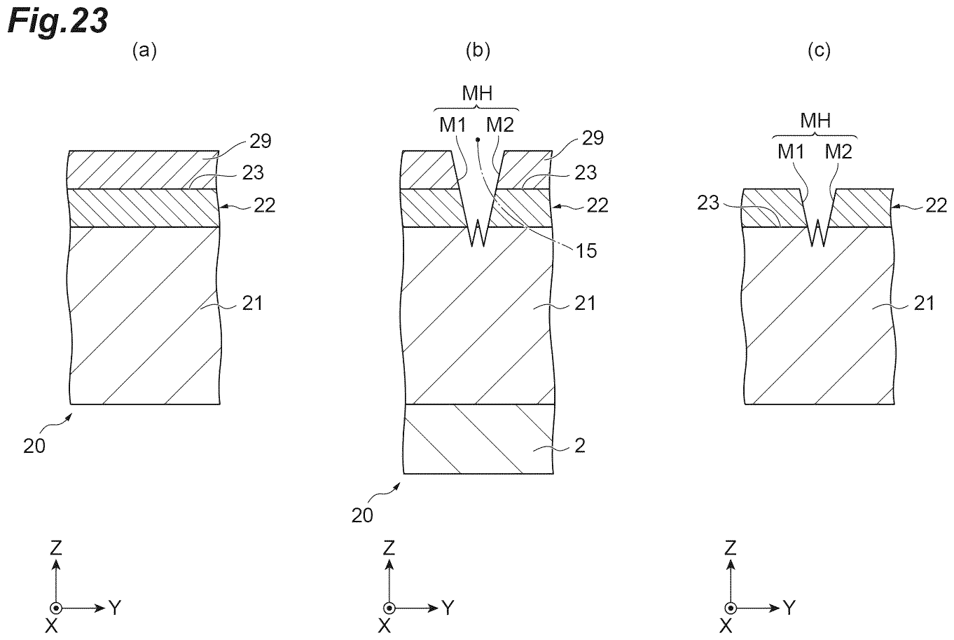

The laser processing method using the laser processing device 100 and the laser processing device 1 is not limited to the method described above, and may be, for example, the following method. That is, first, as shown in FIG. 23(a), the wafer 20 is prepared. The protective film 29 is applied to the surface of the wafer 20 on the functional element layer 22 side. Subsequently, as shown in FIG. 23(b), in the laser processing device 1, the wafer 20 is adsorbed and supported by the support unit 2, and then grooving processing is performed on the wafer 20. In the grooving processing, the control unit 5 controls the irradiation unit 3 so that the street 23 of the wafer 20 is irradiated with the laser light L along the line 15, and the control unit 5 controls the support unit 2 so that the laser light L moves relatively along the line 15. As a result, the surface layer of the street 23 on the wafer 20 is removed to form the composite groove MH.

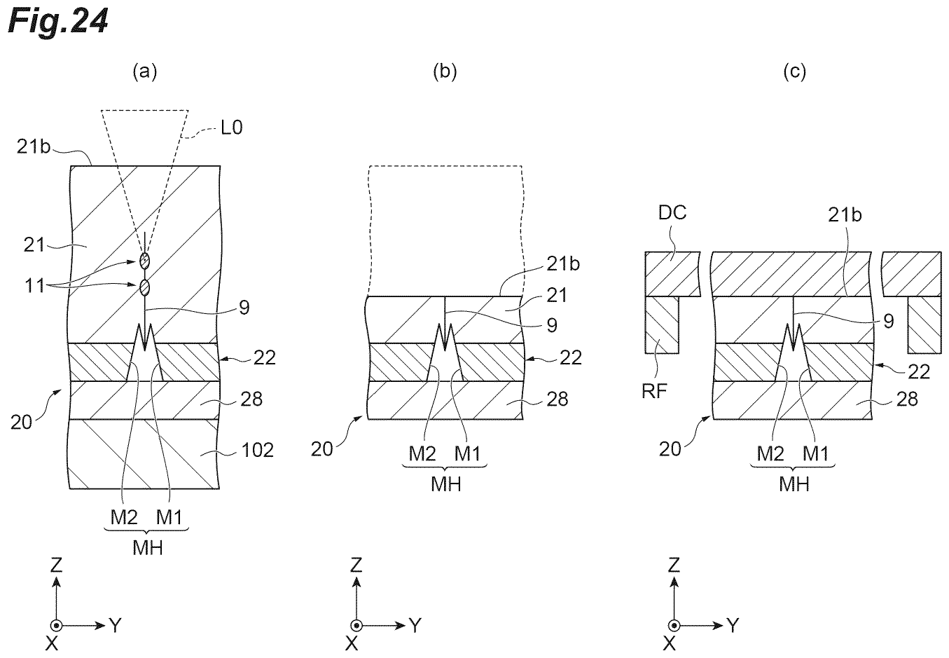

Subsequently, as shown in FIG. 23(c), the wafer 20 is removed from the support unit 2, and the protective film 29 is removed using, for example, a chemical solution. As shown in FIG. 24(a), the grinding tape 28 is attached to the surface of the wafer 20 on the functional element layer 22 side. In the laser processing device 100, the modified region 11 is formed inside the wafer 20 along the line 15 by irradiating the wafer 20 with the laser light L0 along the line 15. Here, after the wafer 20 is adsorbed and supported by the support unit 102, a scan in which the wafer 20 is irradiated with the laser light L0 from the back surface 21b with the focusing point of the laser light L0 aligned inside the semiconductor substrate 21 is repeated multiple times by changing the position of the focusing point in the Z direction. As a result, a plurality of rows of modified regions 11 are formed in the Z direction inside the semiconductor substrate 21, and the cracks 9 extend from the modified regions 11.

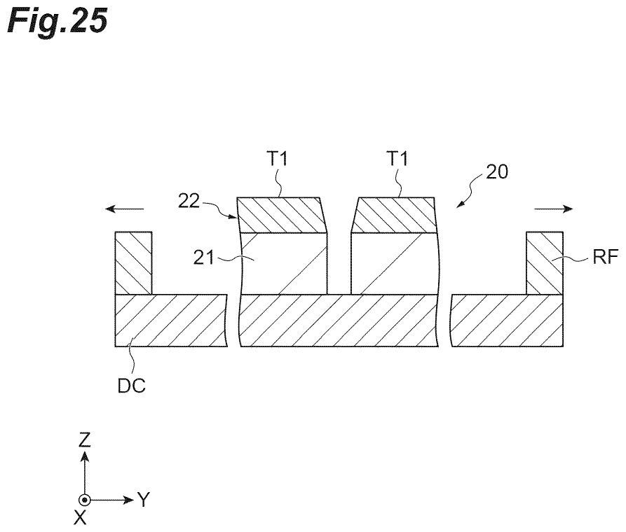

Subsequently, as shown in FIG. 24(b), the back surface 21b side of the semiconductor substrate 21 of the wafer 20 is ground using a grinding device to make the wafer 20 thin up to a desired thickness where the modified region 11 has been removed. As shown in FIG. 24(c), the transparent dicing tape DC provided with the ring frame RF is attached to the back surface 21b of the semiconductor substrate 21 of the wafer 20. Then, as shown in FIG. 25, by expanding the attached transparent dicing tape DC with an expander (not shown), the crack 9 is extended in the thickness direction of the wafer 20 along each line 15, thereby cutting the wafer 20 along the line 15. As a result, the wafer 20 is made into chips corresponding to the respective functional elements 22a, and a plurality of chips Tl are obtained. In the laser processing method according to such a modification example, the wafer 20 can be made thin by grinding after forming the composite groove MH.

In the embodiment and the modification example described above, the imaging unit 4 may include a camera for acquiring image data of the street of the wafer 20 using visible light. In the embodiment and the modification example described above, information to control the irradiation conditions (laser ON/OFF control, laser power) of the laser light L in each region of the street 23 can be created using an image of at least the surface layer of the street 23 after cutting and a perspective image using infrared rays, and grooving processing can be controlled based on this information. In the embodiment and the modification example described above, the surface layer of the street 23 may be removed by scanning the street 23 with the laser light L multiple times. In the embodiment and the modification example described above, only the support unit 102 may be controlled so that the laser light L0 moves relatively along each line 15, or only the laser processing head H may be controlled so that the laser light L0 moves relatively along each line 15, or both the support unit 102 and the laser processing head H may be controlled so that the laser light L0 moves relatively along each line 15. In the embodiment and the modification example described above, only the support unit 2 may be controlled so that the laser light L moves relatively along each street 23, or only the irradiation unit 3 may be controlled so that the laser light L moves relatively along each street 23, or both the support unit 2 and the irradiation unit 3 may be controlled so that the laser light L moves relatively along each street 23.

In the embodiment and the modification example described above, the energy at each focusing point of a plurality of branched laser light components obtained by branching the laser light L may be equal, or may be made stronger or weaker by changing the branching ratio. In the embodiment and the modification example described above, the positions of the focusing points SA1, SA2, and SA3 of the first branched laser light components in the Y direction are the same, but at least one of the positions of the focusing points SA1, SA2, and SA3 of the first branched laser light components in the Y direction may be shifted in the Y direction within a range narrower than the distance Y1. The positions of the focusing points SB1, SB2, and SB3 of the second branched laser light components in the Y direction are the same, but at least one of the positions of the focusing points SB1, SB2, and SB3 of the second branched laser light components in the Y direction may be shifted in the Y direction within a range narrower than the distance Y1. The positions of the focusing points SC1 and SC2 of the third branched laser light components in the Y direction are the same, but at least one of the positions of the focusing points SC1 and SC2 of the third branched laser light components in the Y direction may be shifted in the Y direction within a range narrower than the distance Y1 or the distance Y2. The distance Y1 may be equal to or different from the distance Y2.

In the embodiment and the modification example described above, both the bottom of the first groove M1 and the bottom of the second groove M2 may be located on the front surface 21a of the semiconductor substrate 21. In the embodiment and the modification example described above, the number of branches into which the laser light L is branched by the branching pattern is not limited, and may be plural. In the embodiment and the modification example described above, the end of the crack 9 may reach the inner surface of the first groove M1 or the inner surface of the second groove M2 when forming the modified region 11, or the end of the crack 9 may reach the inner surface of the first groove M1 or the inner surface of the second groove M2 in a step after the modified region 11 is formed. In the embodiment and the modification example described above, “the end of the crack 9 reaches the inner surface of the first groove M1 or the inner surface of the second groove M2” also includes a case where the end of the crack 9 does not reach the inner surface of the first groove M1 or the inner surface of the second groove M2 in a part of the line 15 as long as the processing is performed for the purpose of making the wafer 20 into chips in a subsequent step, for example.

### REFERENCE SIGNS LIST

1: laser processing device, 2: support unit, 9: crack, 11: modified region, 15: line, 20: wafer (object), 21: semiconductor substrate (substrate), 22: functional element layer, 29: protective film, 31: laser light source, 34: condensing unit, 100: laser processing device, 132: spatial light modulator, 132A: display unit, 200: laser processing device, 202: stage (support unit), d12: distance, d23: distance, d34: distance, d45: distance, d56: distance, DC: transparent dicing tape (tape), L: laser light, L0: laser light, LA: first branched laser light, LB: second branched laser light, M1: first groove (groove), M2: second groove (groove), M3: third groove (groove), MH, MH1, MH2, MH3, MH4, MH5, MH6: composite groove, SA1, SA2, SA3: focusing point of first branched laser light, SB1, SB2, SB3: focusing point of second branched laser light, SC1, SC2: focusing point of third branched laser light, Y1, Y2: distance.

1: A laser processing device for forming a groove in an object along a line by irradiating the object with laser light along the line, the device comprising:
a support unit configured to support the object;
a laser light source configured to emit the laser light;
a spatial light modulator including a display unit on which the laser light emitted from the laser light source is incident and configured to modulate the laser light according to a modulation pattern displayed on the display unit; and
a condensing unit configured to condense the laser light modulated by the spatial light modulator onto the object supported by the support unit,
wherein the modulation pattern includes a branching pattern for at least branching the laser light into one or more first branched laser light components to form a first groove and one or more second branched laser light components to form a second groove, and
a distance between a position of a focusing point of the first branched laser light and a position of a focusing point of the second branched laser light adjacent to each other in a direction along the line is larger than a distance between a position of a focusing point of the first branched laser light and a position of a focusing point of the second branched laser light in a width direction of the first groove and the second groove.

2: The laser processing device according to claim 1,
wherein the second groove overlaps an end portion of the first groove in the width direction of the first groove.

3: The laser processing device according to claim 2,
wherein the branching pattern branches the laser light into one or more third branched laser light components to form a third groove in addition to the first branched laser light and the second branched laser light, the third groove overlapping an end portion of the second groove in the width direction of the second groove.

4: The laser processing device according to claim 1,
wherein the distance between the position of the focusing point of the first branched laser light and the position of the focusing point of the second branched laser light adjacent to each other in the direction along the line is larger than a pulse pitch of the laser light.

5: The laser processing device according to claim 1,
wherein a distance between positions of focusing points of the plurality of first branched laser light components in the direction along the line is larger than a pulse pitch of the laser light.

6: The laser processing device according to claim 1,
wherein a distance between positions of focusing points of the plurality of first branched laser light components in the direction along the line is smaller than the distance between the position of the focusing point of the first branched laser light and the position of the focusing point of the second branched laser light adjacent to each other in the direction along the line.

7: The laser processing device according to claim 1,
wherein a distance between positions of focusing points of the plurality of second branched laser light components in the direction along the line is larger than a pulse pitch of the laser light.

8: The laser processing device according to claim 1,
wherein a distance between positions of focusing points of the plurality of second branched laser light components in the direction along the line is smaller than the distance between the position of the focusing point of the first branched laser light and the position of the focusing point of the second branched laser light adjacent to each other in the direction along the line.

9: The laser processing device according to claim 1,
wherein the branching pattern branches the laser light into the two first branched laser light components and the two second branched laser light components.

10: The laser processing device according to claim 1,
wherein the branching pattern branches the laser light into the three first branched laser light components and the three second branched laser light components.

11: The laser processing device according to claim 1,
wherein the branching pattern branches the laser light so that focusing points are aligned in a one-dimensional array along the line.

12: A laser processing method for forming a groove in an object along a line by irradiating the object with laser light along the line, the method comprising:
a step of emitting the laser light, making the emitted laser light incident on a display unit of a spatial light modulator, modulating the laser light according to a modulation pattern displayed on the display unit, and condensing the modulated laser light onto the object,
wherein the modulation pattern includes a branching pattern for at least branching the laser light into one or more first branched laser light components to form a first groove and one or more second branched laser light components to form a second groove, and
a distance between a position of a focusing point of the first branched laser light and a position of a focusing point of the second branched laser light adjacent to each other in a direction along the line is larger than a distance between a position of a focusing point of the first branched laser light and a position of a focusing point of the second branched laser light in a width direction of the first groove and the second groove.
